(19) United States
(12) Patent Application Publication
(10) Pub. No.: US 2026/0052939 A1
(43) Pub. Date: Feb. 19, 2026

(54) HIGH-EFFICIENCY INNER AIR PURGE DESIGN FOR FRAME CASSETTES FOR SEMICONDUCTOR MANUFACTURING

(71) Applicant: Taiwan Semiconductor Manufacturing Company Limited, Hsinchu (TW)

(72) Inventors: Jen-Yuan Chang, Hsinchu City (TW); Jin-Yu Jiang, Hsinchu (TW); Hsiang Chen, Hsinchu (TW); Chi-Yen Lin, Tainan City (TW)

(21) Appl. No.: 18/805,890

(22) Filed: Aug. 15, 2024

(51) Int. Cl. H01L 21/673

(52) U.S. Cl. CPC H01L 21/67389

(57) ABSTRACT

A frame cassette may be provided, which comprises a frame holder holding a vertical stack of substrates, a gas distribution manifold comprising an inlet port and rows of distribution orifices arranged along a vertical direction, and a gas exhaust manifold comprising an outlet port and rows of exhaust orifices arranged along the vertical direction and configured to collect the purge gas. Values of the pneumatic conductance for the rows of distribution orifices increase with a length of a gas flow path within the gas distribution manifold from the inlet port to a respective row of distribution orifices. A lateral flow of the purge gas may be induced between the inlet port and the outlet port by pressuring the inlet port relative to the outlet port while applying a stream of the purge gas to the inlet port.

### BACKGROUND

In the field of semiconductor manufacturing, related frame cassette designs have been plagued by inefficiencies in gas purging processes due to non-uniform ventilation. The related approach typically involves a single bottom vent, which fails to achieve uniform ventilation within the cassette. This inadequacy leads to the retention of internal gases, resulting in surface contamination. Such contamination is a primary cause of non-bond defects, which severely impact manufacturing yields. Inefficient gas purging may result in contamination of surfaces before hybrid and fusion bonding processes, leading to non-bond defects and lower yields. These issues are particularly impactful in advanced packaging technologies. The inability to effectively remove internal gases hampers the overall efficiency and reliability of semiconductor devices produced using these methods.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A-1D are vertical cross-sectional views of various configurations of frame cassette with loaded substrates as positioned over a docking unit according to an embodiment of the present disclosure.

FIGS. 2A-2S are side views of portions of a gas distribution manifold and a gas exhaust manifold of various configurations of the frame cassette of the present disclosure. Each of FIGS. 2A-2S includes, from top to bottom, a side view of a portion of a most distal perforated distribution manifold branch of the gas distribution manifold located between neighboring pairs of substrates, a side view of a portion of a most proximal perforated distribution manifold branch of the gas distribution manifold located between neighboring pairs of substrates, a side view of a portion of a most distal branch of the gas exhaust manifold located between neighboring pairs of substrates, and a side view of a portion of a most proximal branch of the gas exhaust manifold located between neighboring pairs of substrates.

FIGS. 3A-3E are top-down views of various configurations of the frame cassette according to an embodiment of the present disclosure.

FIG. 4 is a first flowchart illustrating steps for flowing a purge gas in a frame cassette according to an embodiment of the present disclosure.

FIG. 5 is a second flowchart illustrating steps for storing substrates in a frame cassette according to an embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Unless explicitly stated otherwise, each element having the same reference numeral is presumed to have the same material composition and to have a thickness within a same thickness range.

Various embodiments disclosed herein are directed to a novel high-efficiency inner air purge design for frame cassettes used in semiconductor manufacturing. Purge gas flow in a related frame cassettes with a single bottom vent provides a non-uniform purge gas flow pattern. This non-uniform purge gas flow patter may lead to the retention of the purge gas in localized volumes. Extended retention of the purge gas in localized volumes may cause the contamination on substrate surfaces, which may result in non-bond defects and reduced manufacturing yields.

Embodiments of the present disclosure use a gas distribution manifold and a gas exhaust manifold that ensures effective and uniform purge gas distribution within a frame cassette. The combination of the gas distribution manifold and the gas exhaust manifold provides a high-efficiency inner air purge design for frame cassettes. The gas distribution manifold may include a plurality of perforated distribution manifold branches. Each of the plurality of perforated distribution manifold branches may include a respective row of distribution orifices, and a plurality of perforated exhaust manifold branches each including a respective row of exhaust orifices. Pneumatic conductance of the row of distribution orifices and pneumatic conductance of the row of exhaust orifices may be varied along the vertical direction so that an increase in the gas travel distance is compensated by a larger pneumatic conductance for each row of distribution orifices and for each row of exhaust orifices. A relatively uniform purge gas flow may be provided within the entire volume of the frame cassette of various disclosed embodiments. Thus, the size and/or the density of the distribution orifices in the gas distribution manifold may increase as a function of a distance from an inlet port to the distribution orifices, and the size and/or the density of the exhaust orifices in the gas exhaust manifold may increase as a function of a distance from the exhaust orifices to an outlet port. The design of the distribution orifices and the exhaust orifices ensures that a purge gas effectively carries away outgassed substances from within the volume of the frame cassette, and thus, prevents surface contamination of substrates and improves the process yield in subsequent processing steps such as bonding steps.

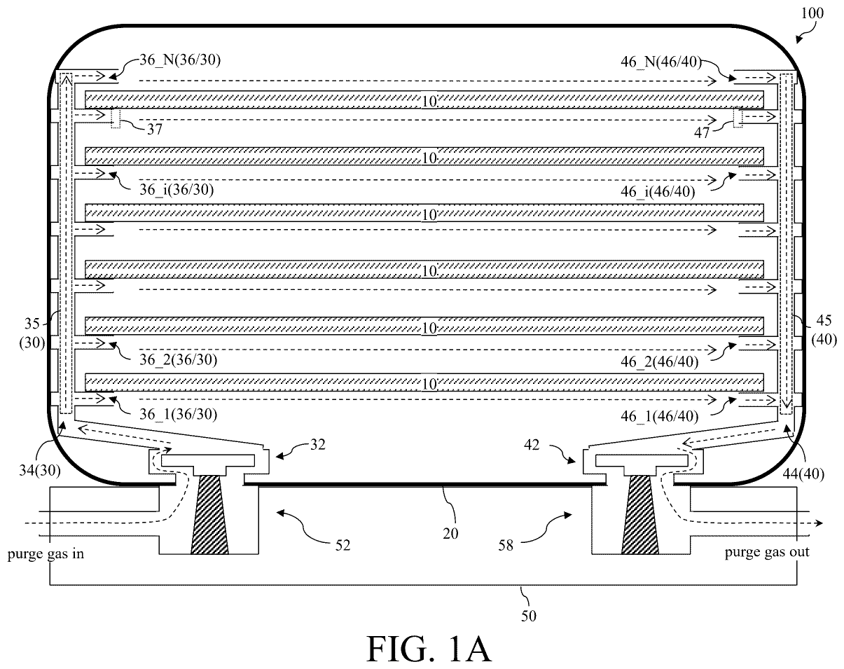

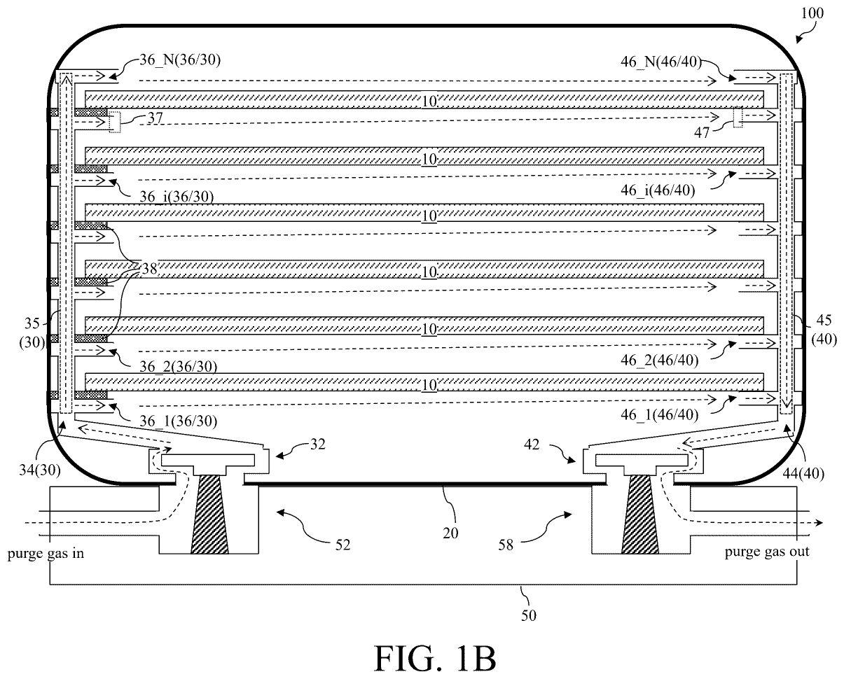

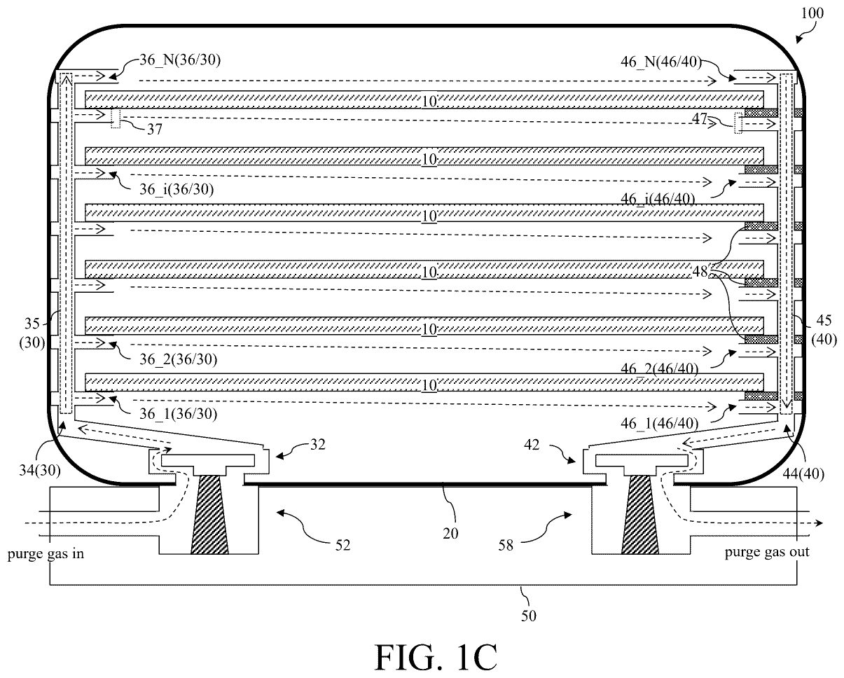

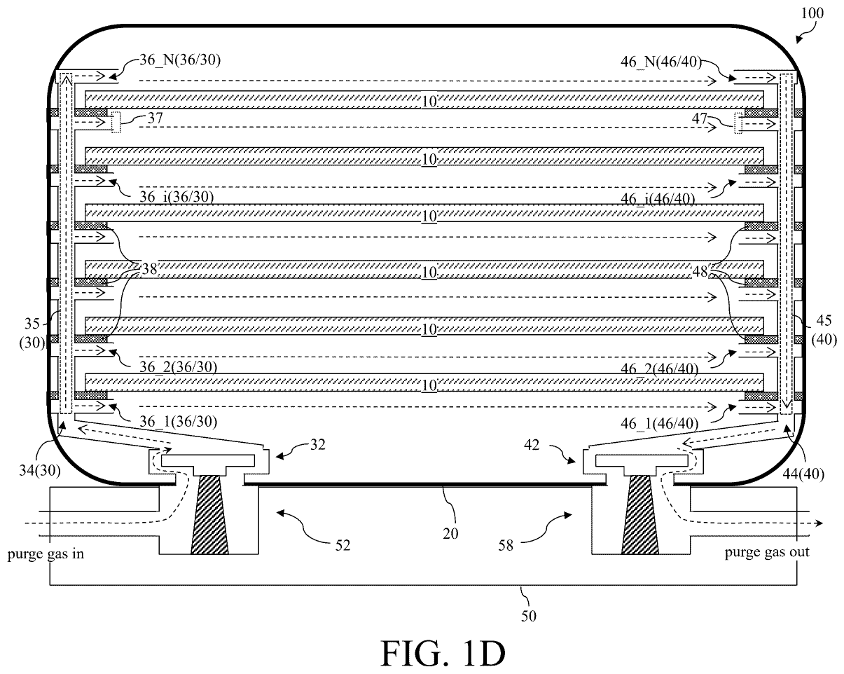

FIGS. 1A-1D are vertical cross-sectional views of various embodiment configurations of frame cassette 100 with loaded substrates 10 as positioned over a docking unit 50 according to an embodiment of the present disclosure. As used herein, a “frame cassette” refers to any apparatus designed to hold and support a vertical stack of substrates 10 (such as semiconductor wafers) during manufacturing processes.

Referring to FIG. 1A, a first configuration of a frame cassette 100 is shown while the frame cassette 100 is loaded with substrates 10 and is positioned over a docking unit 50. According to an aspect of the present disclosure, a frame cassette 100 of the disclosed embodiment may comprise an enclosure wall 20 (which may be a transparent container with an opening for allowing passage of substrates 10 therethrough), a frame holder including mechanical elements for physically supporting the substrates 10 once the substrates 10 are loaded, a gas distribution manifold 30 for distributing a purge gas from the distribution side, and a gas exhaust manifold 40 for collecting the purge gas from the exhaust side. The various components of the frame cassette 100 are configured to manage the flow of the purge gas, ensuring uniform gas distribution and effective purging of contaminants from the substrates 10 while the substrates 10 are stored within the enclosure wall 20.

The gas distribution manifold 30 comprises a distribution manifold main 35 that extends along a vertical direction and having a pair of an inner wall and an outer wall that are parallel to a proximal sidewall of the enclosure wall 20; a plurality of perforated distribution manifold branches 36 that are arranged along the vertical direction, are vertically spaced apart from one another, are adjoined to the distribution manifold main 35, and including a respective row of distribution orifices 37 that face the center region within the volume of the enclosure inside the enclosure wall 20; and an inlet port 34 that is located in proximity to the path of the purge gas through which the purge gas enters the enclosure inside the enclosure wall 20.

The gas exhaust manifold 40 comprises an exhaust manifold main 45 that extends along a vertical direction and having a pair of an inner wall and an outer wall that are parallel to a proximal sidewall of the enclosure wall 20; a plurality of perforated exhaust manifold branches 46 that are arranged along the vertical direction, are vertically spaced apart from one another, are adjoined to the exhaust manifold main 45, and including a respective row of exhaust orifices 47 that face the center region within the volume of the enclosure inside the enclosure wall 20; and an outlet port 44 that is located in proximity to the path of the purge gas through which the purge gas exits the enclosure outside the enclosure wall 20.

The frame cassette 100 may further comprise a gas inlet seal 32 configured to provide a gas inlet passage toward the inlet port 34 upon docking with a mating gas supply connector 52 within the docking unit 50; and a gas outlet seal 42 configured to provide a gas outlet passage from the outlet port 44 upon docking with a mating gas exhaust connector 58 within the docking unit 50. The various dotted arrows represent the flow direction of the purge gas, which may comprise, and/or consist essentially of, nitrogen or clean dry air (CDA). The gas supply connector 52 and the gas exhaust connector 58 may be provided with various seal mechanisms, automatic valves, filters, and/or other mechanical components known in the art for providing secure and leak-tight connection upon docking of the frame cassette 100 with the docking unit 50.

The substrates 10 may be any type of substrates used in semiconductor manufacturing. Non-limiting examples of the substrates 10 include silicon wafers with various semiconductor devices and/or interconnect-level dielectric material layers, organic interposer substrates including a two-dimensional organic interposers prior to dicing, a reconstituted wafer including a two-dimensional array of semiconductor dies formed within a molding compound matrix, etc. The shapes of the substrates 10 in a top-down view may be circular shapes, rectangular shapes, rounded rectangular shapes, or any other shapes having a suitable periphery that provides stable physical support upon landing on surfaces of the frame holder (30, 40).

The frame holder (30, 40) collectively refers to the set of all mechanical components that may be used to hold the substrates 10 in place while the substrates 10 are stored within the enclosure wall 20. Thus, the frame holder (30, 40) is a functional element that provides the function of supporting the substrates 10. As such, the frame holder (30, 40) may use dedicated mechanical components without utilizing the gas distribution manifold 30 and/or the gas exhaust manifold 40, or may utilize the physical structures of the gas distribution manifold 30 and/or the gas exhaust manifold 40. In the illustrated example of FIG. 1A, the frame holder (30, 40) comprises a combination of the gas distribution manifold 30 and the gas exhaust manifold 40, and utilizes the geometrical features of the gas distribution manifold 30 and the gas exhaust manifold 40 to provide stable mechanical support to the substrates 10.

In one embodiment, the perforated distribution manifold branches 36 may have shapes of ledges that are attached to an inner sidewall of the enclosure wall 20. The width of the lateral protrusion of the ledges (comprising the physical surfaces of the perforated distribution manifold branches 36) may be selected to provide an areal overlap with a peripheral region of an overlying substrate 10 to provide stable mechanical support to the overlying substrate 10. For example, the maximum width of the contact area between a perforated distribution manifold branch 36 and an overlying substrate 10 may be in a range from 1 mm to 10 mm, although lesser and greater widths may also be used. Likewise, the perforated exhaust manifold branches 46 may have shapes of ledges that are attached to another inner sidewall of the enclosure wall 20. The width of the lateral protrusion of the ledges (comprising the physical surfaces of the perforated exhaust manifold branches 46) may be selected to provide a sufficient areal overlap with a peripheral region of an overlying substrate 10 to provide stable mechanical support to the overlying substrate 10. For example, the maximum width of the contact area between a perforated exhaust manifold branch 46 and an overlying substrate 10 may be in a range from 1 mm to 10 mm, although lesser and greater widths may also be used.

Each of the perforated distribution manifold branches 36 comprises a respective row of distribution orifices 37 configured to inject a purge gas between vertically neighboring pairs of the substrates 10, above the topmost substrate 10, or below the bottommost substrate 10. Each row of distribution orifices 37 may be arranged along a horizontal direction, which may be the horizontal direction along which the distribution manifold main 35 laterally extends. Each row of distribution orifices 37 has a respective value for pneumatic conductance.

As used herein, “pneumatic conductance” refers to the ease with which a gas may flow through a perforated surface or orifice. Generally, in instances in which a gas passes through an orifice or a porous medium, the rate at which the gas flows is determined by factors such as the size, shape, and number of the orifices, as well as the pressure differential across them. Thus, the greater the size and number of orifices, the higher the pneumatic conductance, allowing for more efficient gas flow. Pneumatic conductance is a measure of this flow rate and is typically quantified in terms of volume flow per unit of pressure difference. Pneumatic conductance for any perforated surface may be defined by the formula C=Q/ΔP, where C represents pneumatic conductance, Q represents the volumetric flow rate of the gas, and ΔP represents the pressure difference across the surface. The value of pneumatic conductance for any perforated surface may be calculated by considering the combined effects of all the individual orifices, taking into account their respective sizes, shapes, and distribution.

According to an aspect of the present disclosure, the values of the pneumatic conductance for the rows of distribution orifices 37 increase with the length of the gas flow path within the gas distribution manifold 30 from the inlet port 34 to a respective row of distribution orifices 37, i.e., to a respective perforated distribution manifold branch 36. For example, the perforated distribution manifold branches 36 may be sequentially numbered with positive integers beginning with 1 in the order of the length of the gas flow path within the gas distribution manifold 30 from the inlet port 34 to the respective perforated distribution manifold branch 36. In instances in which the total number of perforated distribution manifold branches 36 is N, the perforated distribution manifold branches 36 may comprise a first perforated distribution manifold branch 36_1 that has the shortest gas flow path from the inlet port 34, a second perforated distribution manifold branch 36_2 that has the next shortest gas flow path from the inlet port 34, and so on, and the N-th perforated distribution manifold branch 36_N that has the longest gas flow path from the inlet port 34. For any positive integer i less than (N+1), an i-th perforated distribution manifold branch 36_i is provided. The value of the integer N may be in a range from 2 to 51, such as from 3 to 26.

According to embodiments of the present disclosure, the values of the pneumatic conductance for the rows of exhaust orifices 47 increase with the length of the gas flow path within the gas exhaust manifold 40 from a respective row of exhaust orifices 47, i.e., from a respective perforated exhaust manifold branch 46, to the outlet port 44. For example, the perforated exhaust manifold branches 46 may be sequentially numbered with positive integers beginning with 1 in the order of the length of the gas flow path within the gas exhaust manifold 40 from the respective perforated exhaust manifold branch 46 to the outlet port 44. In instances in which the total number of perforated exhaust manifold branches 46 is N, the perforated exhaust manifold branches 46 may comprise a first perforated exhaust manifold branch 46_1 that has the shortest gas flow path to the outlet port 44, a second perforated exhaust manifold branch 46_2 that has the next shortest gas flow path to the outlet port 44, and so on, and the N-th perforated exhaust manifold branch 46_N that has the longest gas flow path to the outlet port 44. For any positive integer i less than (N+1), an i-th perforated exhaust manifold branch 46_i is provided.

A lateral flow of the purge gas may be induced between the inlet port 34 and the outlet port 44 by pressuring the inlet port 34 relative to the outlet port 44 while applying a stream of the purge gas to the inlet port 34. The purge gas carries away outgassed molecules from the various materials of the substrates 10, thereby preventing reaction of the outgassed molecules with other materials on the substrates 10. Thus, formation of reaction byproducts on the surfaces of the substrates 10 may be mitigated and even avoided.

The pneumatic conductance of the distribution manifold main 35 is finite, and the pneumatic conductance of the exhaust manifold main 45 is also finite. Thus, the flow rate of the purge gas from the inlet port 34 to the perforated distribution manifold branches 36 would decrease as a function of the length of the gas flow path through the distribution manifold main 35 if the pneumatic conductance of each perforated distribution manifold branches 36 were to be the same. According to an aspect of the present disclosure, the values of the pneumatic conductance for the rows of distribution orifices 37 increase with the length of the gas flow path within the gas distribution manifold 30 from the inlet port 34 to a respective perforated distribution manifold branch 36 by amounts that compensate for the decrease in the purge gas flow due to the differences in the gas flow distance through the distribution manifold main 35. Thus, the flow rate of the purge gas through each row of distribution orifices 37 (i.e., through each perforated distribution manifold branch 36) may be the same or may be substantially the same (e.g., within +/−20%, and more preferably within +/−10% of a target value). In some embodiments, the flow rate of the purge gas through the bottommost perforated distribution manifold branch 36 (i.e., the first perforated distribution manifold branch 36_1) and/or through the topmost perforated distribution manifold branch 36 (i.e., the N-th perforated distribution manifold branch 36_N) may be adjusted as necessary to account for the differences in the volumes to which the purge gas is injected.

Likewise, the flow rate of the purge gas from the perforated exhaust manifold branches 46 to the outlet port 44 would decrease as a function of the length of the gas flow path through the exhaust manifold main 45 in instances in which the pneumatic conductance of each perforated exhaust manifold branches 46 were to be the same. According to an aspect of the present disclosure, the values of the pneumatic conductance for the rows of exhaust orifices 47 increase with the length of the gas flow path within the gas exhaust manifold 40 from a respective perforated exhaust manifold branch 46 to the outlet port 44 by amounts that compensate for the decrease in the purge gas flow due to the differences in the gas flow distance through the exhaust manifold main 45. Thus, the flow rate of the purge gas through each row of exhaust orifices 47 (i.e., through each perforated exhaust manifold branch 46) may be the same or may be substantially the same (e.g., within +/−20%, and more preferably within +/−10% of a target value). In some embodiments, the flow rate of the purge gas through the bottommost perforated exhaust manifold branch 46 (i.e., the first perforated exhaust manifold branch 46_1) and/or through the topmost perforated exhaust manifold branch 46 (i.e., the N-th perforated exhaust manifold branch 46_N) may be adjusted as necessary to account for the differences in the volumes to which the purge gas is injected.

Generally, the values of the pneumatic conductance for the rows of distribution orifices 37 increase with the length of the gas flow path within the gas distribution manifold 30 from the inlet port 34 to a respective row of distribution orifices 37 at least for a set of perforated distribution manifold branches 36 that excludes the bottommost perforated distribution manifold branch 36 (i.e., the first perforated distribution manifold branch 36_1) and the topmost perforated distribution manifold branch 36 (i.e., the N-th perforated distribution manifold branch 36_N). Further, the values of the pneumatic conductance for the rows of exhaust orifices 47 increase with the length of the gas flow path within the gas exhaust manifold 40 from a respective row of exhaust orifices 47 at least for a set of perforated exhaust manifold branches 46 that excludes the bottommost perforated exhaust manifold branch 46 (i.e., the first perforated exhaust manifold branch 46_1) and the topmost perforated exhaust manifold branch 46 (i.e., the N-th perforated exhaust manifold branch 46_N).

It is to be understood that when a gas distribution manifold “comprises” rows of distribution orifices 37 or perforated distribution manifold branches, such rows or such manifold branches may, or may not, include each and every row, or each and every manifold branch. Likewise, when a gas exhaust manifold “comprises” rows of exhaust orifices 47 or perforated exhaust manifold branches, such rows or such manifold branches may, or may not, include each and every row, or each and every manifold branch. For any set of at least two rows of distribution orifices 37 within the set of perforated distribution manifold branches 36 that excludes the bottommost perforated distribution manifold branch 36 (i.e., the first perforated distribution manifold branch 36_1) and the topmost perforated distribution manifold branch 36 (i.e., the N-th perforated distribution manifold branch 36_N), the values of the pneumatic conductance for the rows of distribution orifices 37 increase with the length of the gas flow path within the gas distribution manifold 30 from the inlet port 34 to a respective row of distribution orifices 37. Likewise, for any set of at least two rows of exhaust orifices 47 within the set of perforated exhaust manifold branches 46 that excludes the bottommost perforated exhaust manifold branch 46 (i.e., the first perforated exhaust manifold branch 46_1) and the topmost perforated exhaust manifold branch 46 (i.e., the N-th perforated exhaust manifold branch 46_N), the values of the pneumatic conductance for the rows of exhaust orifices 47 increase with the length of the gas flow path within the gas exhaust manifold 40 from a respective row of exhaust orifices 47 to the outlet port 44.

The modulation of pneumatic conductance across the perforated distribution manifold branches 36 and/or the modulation of pneumatic conductance across the perforated exhaust manifold branches 46 may provide the same flow rate or approximately the same flow rate of the purge gas throughout the entire physically exposed surfaces of the substrates 10, and may effectively address any outgassing issue caused by the material composition of the substrates 10.

Generally, the frame holder (30, 40) may be provided in various embodiment configurations. In the first embodiment configuration of the frame cassette 100 illustrated in FIG. 1A, the gas distribution manifold 30 comprising a portion of the frame holder (30, 40) and comprises perforated distribution manifold branches 36; each of the perforated distribution manifold branches 36 comprises a respective sidewall containing a respective row of distribution orifices 37 selected from the rows of distribution orifices 37; and each of the perforated distribution manifold branches 36 is configured to support a peripheral portion of a respective one of the substrates 10. Further, the gas exhaust manifold 40 comprising a portion of the frame holder (30, 40) and comprises perforated exhaust manifold branches 46; each of the perforated exhaust manifold branches 46 comprises a respective sidewall containing a respective row of exhaust orifices 47 selected from the rows of exhaust orifices 47; and each of the perforated exhaust manifold branches 46 is configured to support a peripheral portion of a respective one of the substrates 10.

Referring to FIG. 1B, a second embodiment configuration of the frame cassette 100 of the present disclosure is illustrated. The second embodiment configuration of the frame cassette 100 may be derived from the first configuration of the frame cassette 100 illustrated in FIG. 1A by using a set of additional mechanical structures as a component of the frame holder (30, 40, 38). Specifically, in the second embodiment configuration of the frame cassette 100 illustrated in FIG. 1B, the gas distribution manifold 30 may be shifted downward by a vertical offset distance relative to the first embodiment configuration of the frame cassette 100 without shifting the gas exhaust manifold 40 in the first configuration of the frame cassette 100 illustrated in FIG. 1A. Generally, the vertical offset distance is less than the vertical spacing between neighboring pairs of substrates 10 in the first embodiment configuration of the frame cassette 100 illustrated in FIG. 1A. In the second embodiment configuration of the frame cassette 100, distribution-side spacers 38 may be mounted on the top surfaces of the perforated distribution manifold branches 36 except on the top surface of the topmost perforated distribution manifold branch 36. The distribution-side spacers 38 may comprise any structurally sturdy material such as glass, plastic, metal, etc., and may have a vertical thickness that equals the vertical offset distance. Thus, the substrates 10 may be located on the top surfaces of the distribution-side spacers 38 and on the top surfaces of the ledges comprising top surfaces of the perforated exhaust manifold branches 46.

In the second embodiment configuration, the frame holder (30, 40, 38) comprises distribution-side spacers 38 configured to support a peripheral portion of a respective one of the substrates 10; the gas distribution manifold 30 comprises perforated distribution manifold branches 36 each comprising a respective sidewall containing a respective row of distribution orifices 37 selected from the rows of distribution orifices 37; and each of the distribution-side spacers 38 contacts a top surface of a respective one of the perforated distribution manifold branches 36.

In the second embodiment configuration, for each facing pair of a perforated distribution manifold branch 36 and a perforated exhaust manifold branch 46 located between a respective neighboring pair of substrates 10, the perforated distribution manifold branch 36 is shifted downward relative to the perforated exhaust manifold branch 46. Once the purge gas flows inside the enclosure wall 20, a gas velocity vector field may be calculated within the entire volume inside the enclosure wall 20 that is not filled with any solid phase material. Due to the vertical offset between the facing pair of a perforated distribution manifold branch 36 and a perforated exhaust manifold branch 46 between each vertically neighboring pair of substrates 10, the average of the gas velocity vectors between each vertically neighboring pair of substrates 10 (as calculated within a respective volume bounded by the vertically neighboring pair of substrates 10 and the peripheries of the substrates 10 as seen in a plan view such as a see-through top-down view) includes a horizontal component from the perforated distribution manifold branch 36 and the perforated exhaust manifold branch 46, and further includes an upward vertical component. Thus, for each pair of a row of distribution orifices 37 and a row of exhaust orifices 47 located between a respective vertically neighboring pair of substrates 10 selected from the vertical stack of substrates 10, an average of gas velocity vectors representing a gas flow velocity of the purge gas has a non-zero vertical component.

Referring to FIG. 1C, a third embodiment configuration of the frame cassette 100 of the present disclosure is illustrated. The third embodiment configuration of the frame cassette 100 may be derived from the first embodiment configuration of the frame cassette 100 illustrated in FIG. 1A by using a set of additional mechanical structures as a component of the frame holder (30, 40, 48). Specifically, in the third embodiment configuration of the frame cassette 100 illustrated in FIG. 1C, the gas exhaust manifold 40 may be shifted downward by a vertical offset distance relative to the first embodiment configuration of the frame cassette 100 without shifting the gas distribution manifold 30 in the first embodiment configuration of the frame cassette 100 illustrated in FIG. 1A. Generally, the vertical offset distance is less than the vertical spacing between neighboring pairs of substrates 10 in the first configuration of the frame cassette 100 illustrated in FIG. 1A. In the third embodiment configuration of the frame cassette 100, exhaust-side spacers 48 may be mounted on the top surfaces of the perforated exhaust manifold branches 46 except on the top surface of the topmost perforated exhaust manifold branch 46. The exhaust-side spacers 48 may comprise any structurally sturdy material such as glass, plastic, metal, etc., and may have a vertical thickness that equals the vertical offset distance. Thus, the substrates 10 may be located on the top surfaces of the exhaust-side spacers 48 and on the top surfaces of the ledges comprising top surfaces of the perforated distribution manifold branches 36.

In the third embodiment configuration, the frame holder (30, 40, 38) comprises exhaust-side spacers 48 configured to support a peripheral portion of a respective one of the substrates 10; the gas exhaust manifold 40 comprises perforated exhaust manifold branches 46 each comprising a respective sidewall containing a respective row of exhaust orifices 47 selected from the rows of exhaust orifices 47; and each of the exhaust-side spacers 48 contacts a top surface of a respective one of the perforated exhaust manifold branches 46.

In the third embodiment configuration, for each facing pair of a perforated distribution manifold branch 36 and a perforated exhaust manifold branch 46 located between a respective neighboring pair of substrates 10, the perforated distribution manifold branch 36 is shifted upward relative to the perforated exhaust manifold branch 46. Once the purge gas flows inside the enclosure wall 20, a gas velocity vector field may be calculated within the entire volume inside the enclosure wall 20 that is not filled with any solid phase material. Due to the vertical offset between the facing pair of a perforated distribution manifold branch 36 and a perforated exhaust manifold branch 46 between each vertically neighboring pair of substrates 10, the average of the gas velocity vectors between each vertically neighboring pair of substrates 10 (as calculated within a respective volume bounded by the vertically neighboring pair of substrates 10 and the peripheries of the substrates 10 as seen in a plan view such as a see-through top-down view) includes a horizontal component from the perforated distribution manifold branch 36 and the perforated exhaust manifold branch 46, and further includes a downward vertical component. Thus, for each pair of a row of distribution orifices 37 and a row of exhaust orifices 47 located between a respective vertically neighboring pair of substrates 10 selected from the vertical stack of substrates 10, an average of gas velocity vectors representing a gas flow velocity of the purge gas has a non-zero vertical component.

Referring to FIG. 1D, a fourth embodiment configuration of the frame cassette 100 of the present disclosure is illustrated. The fourth embodiment configuration of the frame cassette 100 may be derived from the second embodiment configuration of the frame cassette 100 illustrated in FIG. 1B by using a set of additional mechanical structures as a component of the frame holder (30, 40, 38, 48). Specifically, in the fourth embodiment configuration of the frame cassette 100 illustrated in FIG. 1D, the gas exhaust manifold 40 may be shifted downward by a vertical offset distance relative to the second embodiment configuration of the frame cassette 100 illustrated in FIG. 1B. The vertical offset distance for the gas exhaust manifold 40 may be the same as the vertical offset distance for the gas distribution manifold 30 used in the second embodiment configuration of the frame cassette illustrated in FIG. 1B. In the fourth embodiment configuration of the frame cassette 100, exhaust-side spacers 48 may be mounted on the top surfaces of the perforated exhaust manifold branches 46 except on the top surface of the topmost perforated exhaust manifold branch 46 in the same manner as in the third embodiment configuration of the frame cassette 100 illustrated in FIG. 1C. Thus, the substrates 10 may be located on the top surfaces of the distribution-side spacers 38 and on the top surfaces of the exhaust-side spacers 48.

In the fourth embodiment configuration, the frame holder (30, 40, 38, 48) comprises distribution-side spacers 38 configured to support a peripheral portion of a respective one of the substrates 10; the gas distribution manifold 30 comprises perforated distribution manifold branches 36 each comprising a respective sidewall containing a respective row of distribution orifices 37 selected from the rows of distribution orifices 37; and each of the distribution-side spacers 38 contacts a top surface of a respective one of the perforated distribution manifold branches 36. In addition, the frame holder (30, 40, 38, 48) further comprises exhaust-side spacers 48 configured to support a peripheral portion of a respective one of the substrates 10; the gas exhaust manifold 40 comprises perforated exhaust manifold branches 46 each comprising a respective sidewall containing a respective row of exhaust orifices 47 selected from the rows of exhaust orifices 47; and each of the exhaust-side spacers 48 contacts a top surface of a respective one of the perforated exhaust manifold branches 46.

In the fourth embodiment configuration, for each facing pair of a perforated distribution manifold branch 36 and a perforated exhaust manifold branch 46 located between a respective neighboring pair of substrates 10, the perforated distribution manifold branch 36 may be level relative to the perforated exhaust manifold branch 46. Once the purge gas flows inside the enclosure wall 20, a gas velocity vector field may be calculated within the entire volume inside the enclosure wall 20 that is not filled with any solid phase material. The average of the gas velocity vectors between each vertically neighboring pair of substrates 10 (as calculated within a respective volume bounded by the vertically neighboring pair of substrates 10 and the peripheries of the substrates 10 as seen in a plan view such as a see-through top-down view) includes a horizontal component from the perforated distribution manifold branch 36 and the perforated exhaust manifold branch 46, and does not include any vertical component.

Referring collectively to FIGS. 1A-1D, a method of storing substrates 10 in a frame cassette 100 is provided. First, a frame cassette 100 is provided, which comprises a frame holder {30, 40, (38/48)}, a gas distribution manifold 30 comprising an inlet port 34 and rows of distribution orifices 37 arranged along a vertical direction configured to inject a purge gas, and a gas exhaust manifold 40 comprising an outlet port 44 and rows of exhaust orifices 47 arranged along the vertical direction and configured to collect the purge gas. According to an aspect of the present disclosure, each row of distribution orifices 37 has a respective value for pneumatic conductance, and values for the pneumatic conductance increase with the length of the gas flow path within the gas distribution manifold 30 from the inlet port 34 to a respective row of distribution orifices 37. The method further comprises loading substrates 10 onto the frame holder {30, 40, (38/48)} such that, for each vertically neighboring pair of substrates 10 selected from the substrates 10, a respective row of distribution orifices 37 and a respective row of exhaust orifices 47 face each other between said each vertically neighboring pair. A lateral flow of the purge gas may be induced between the inlet port 34 and the outlet port 44 by pressuring the inlet port 34 relative to the outlet port 44 while applying a stream of the purge gas to the inlet port 34.

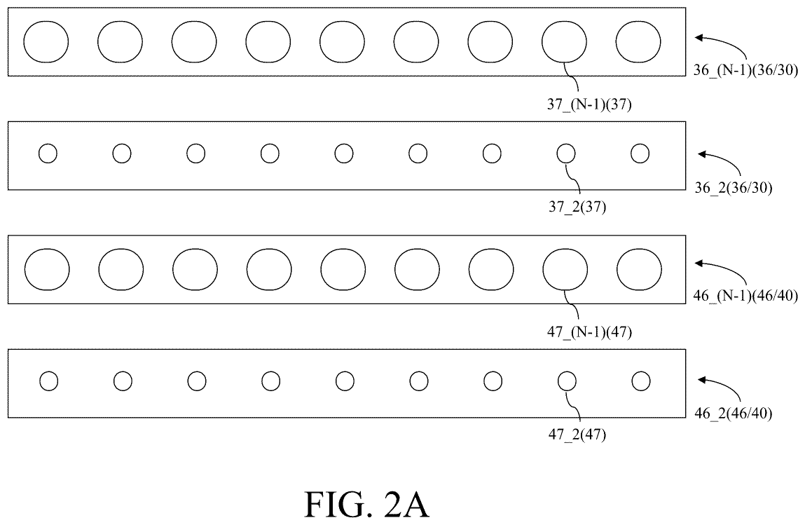

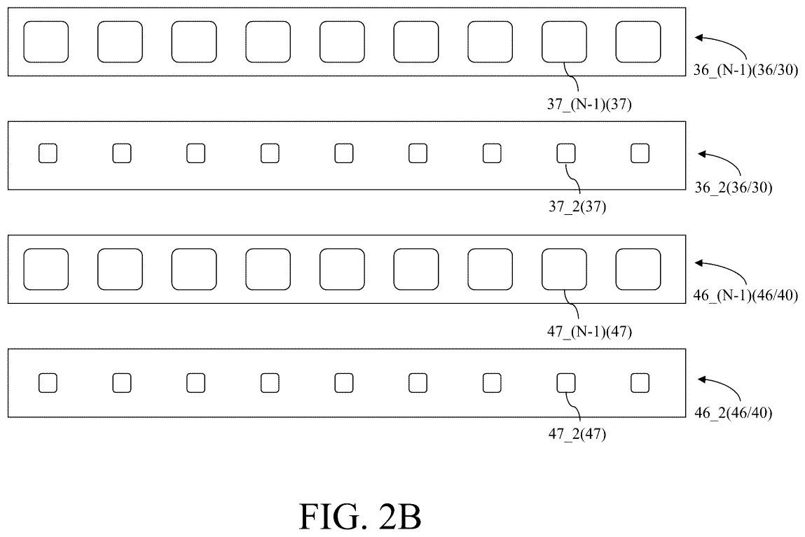

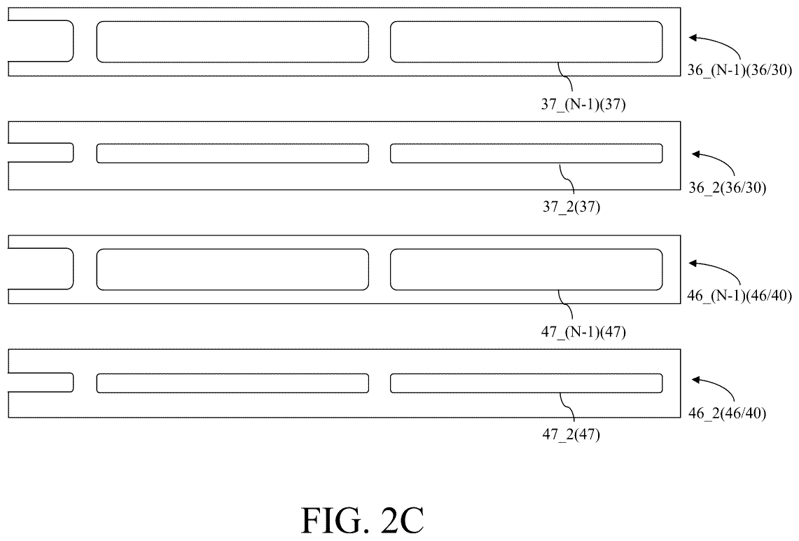

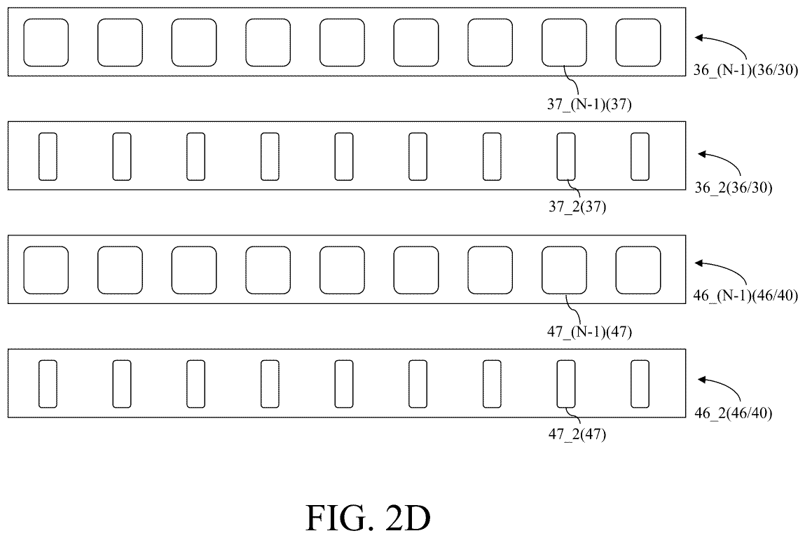

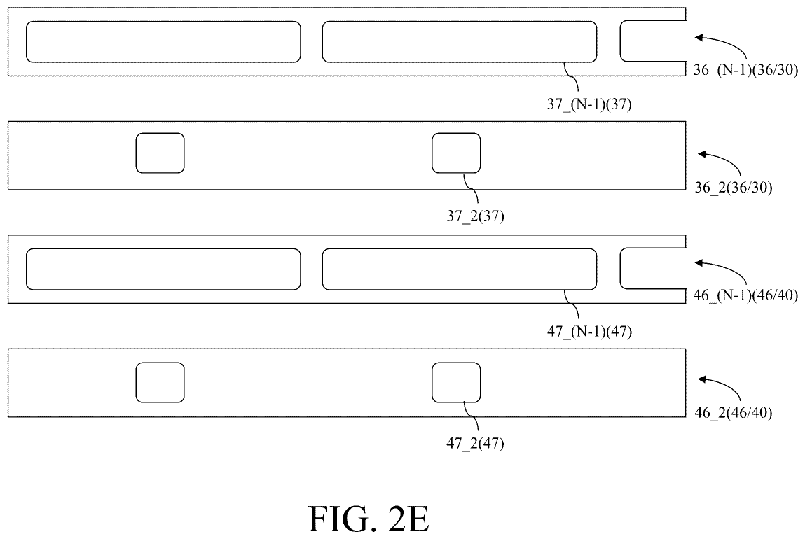

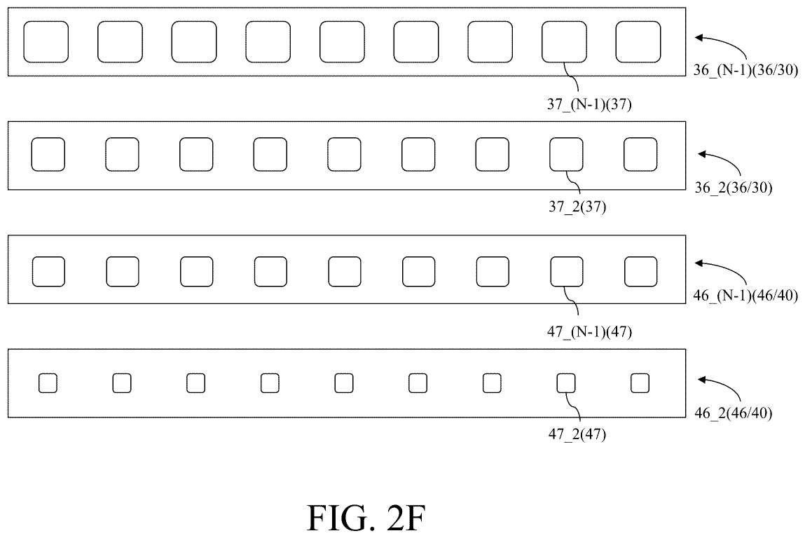

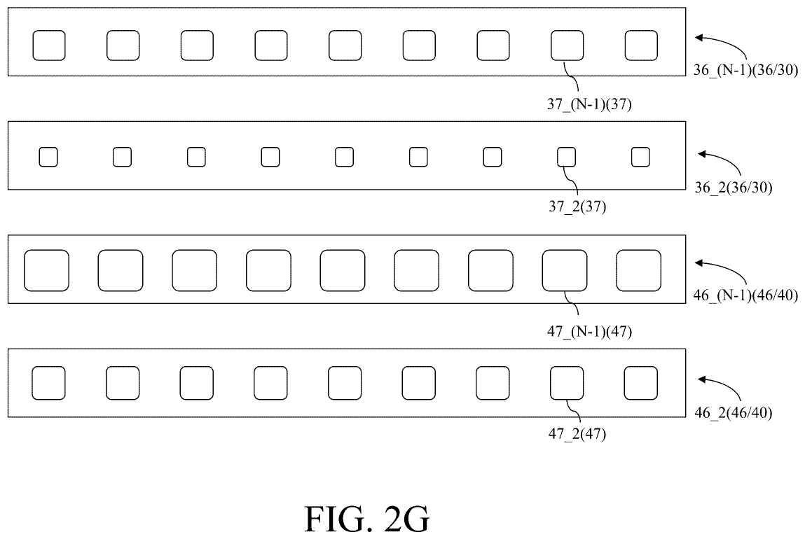

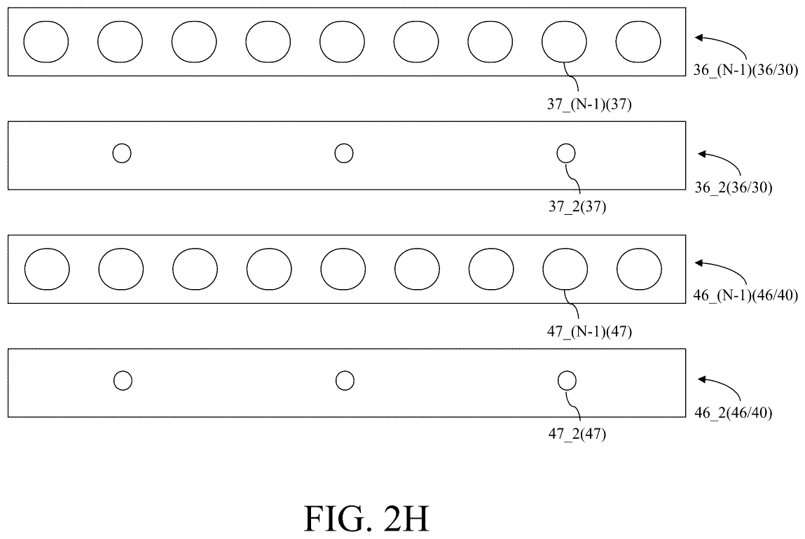

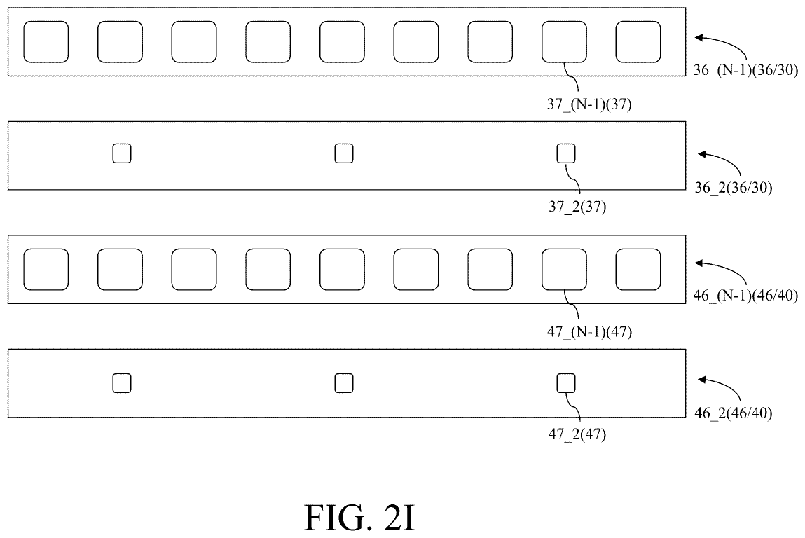

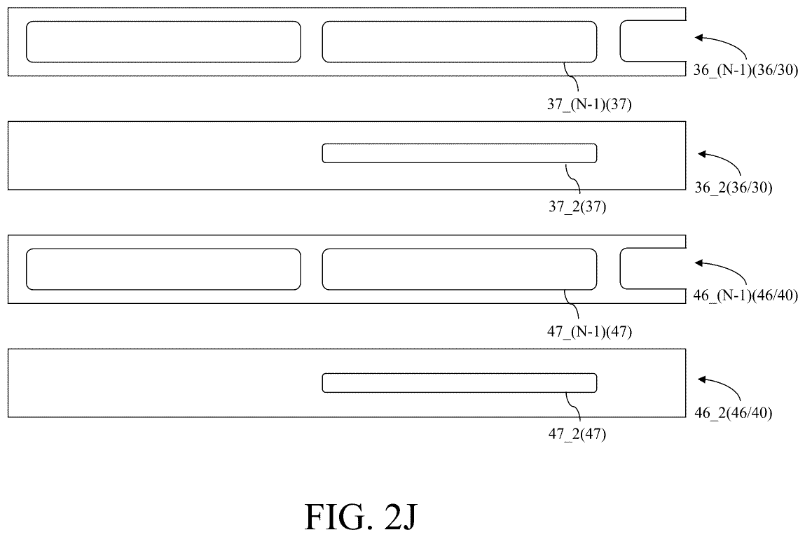

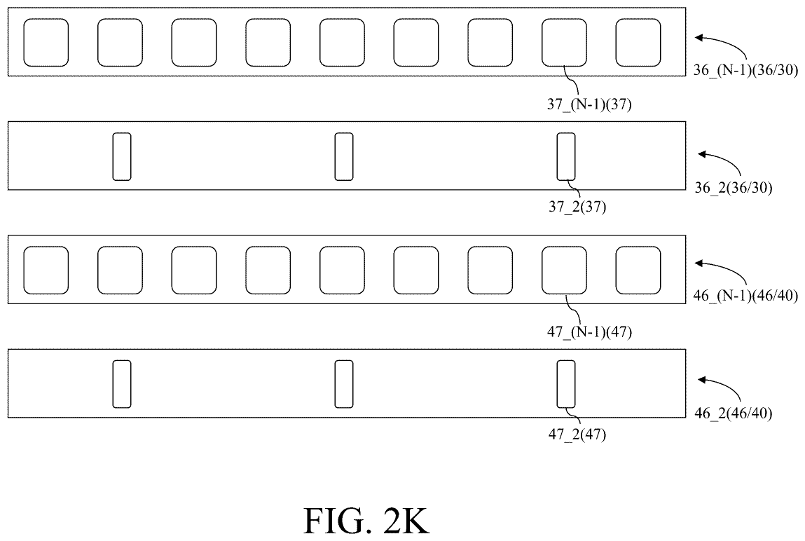

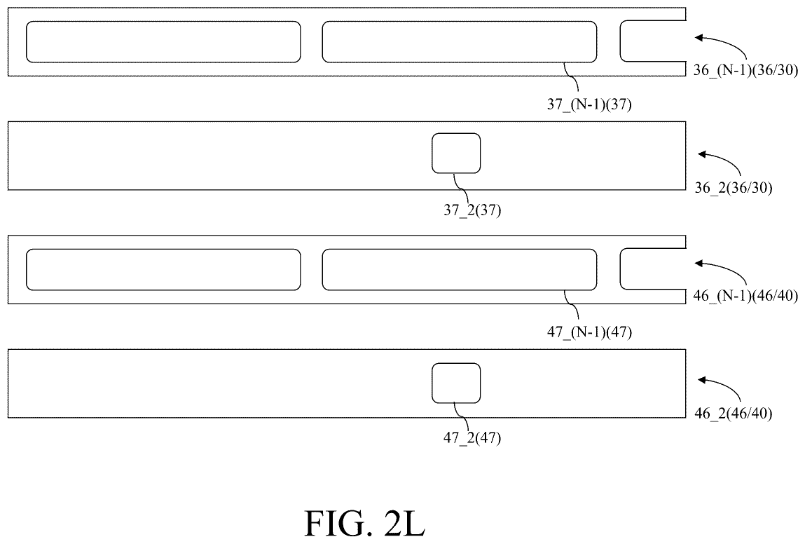

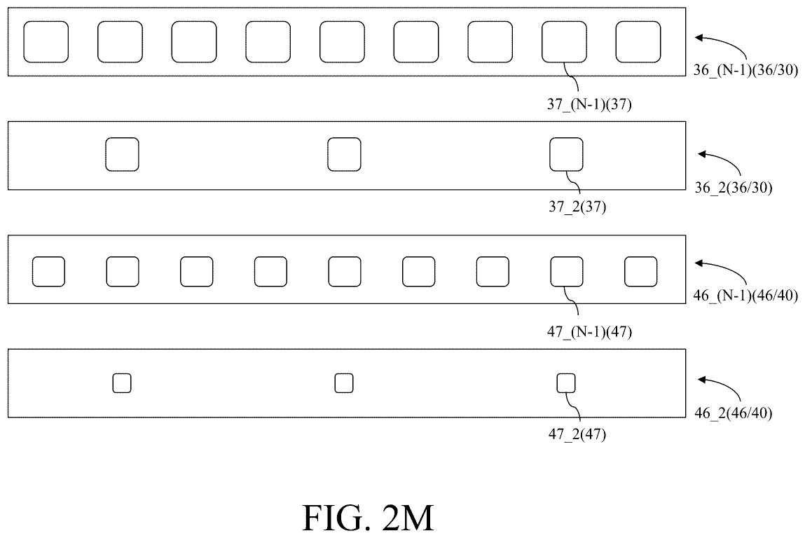

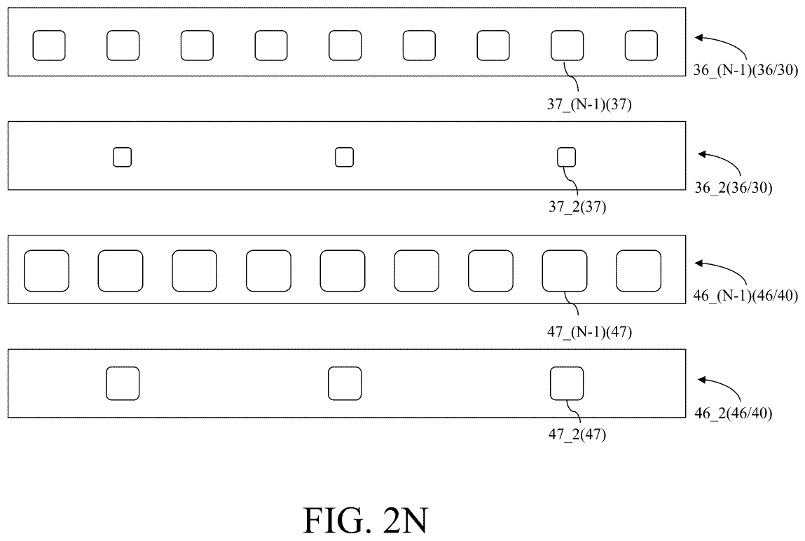

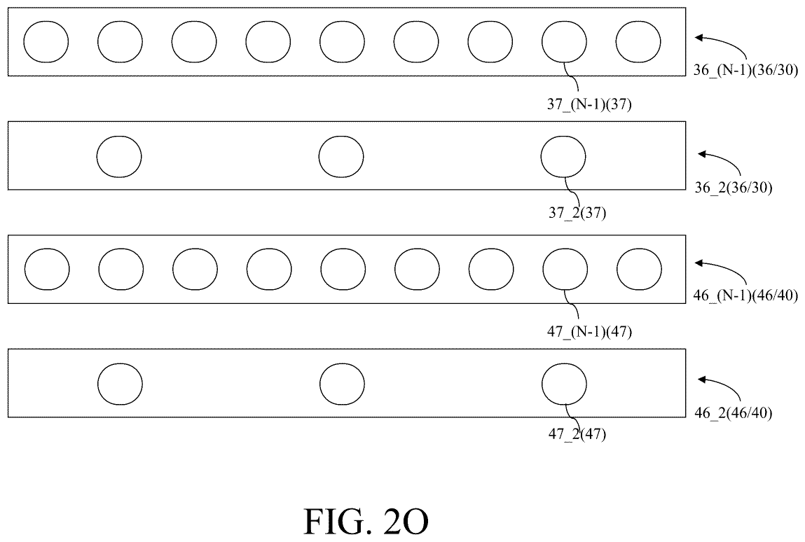

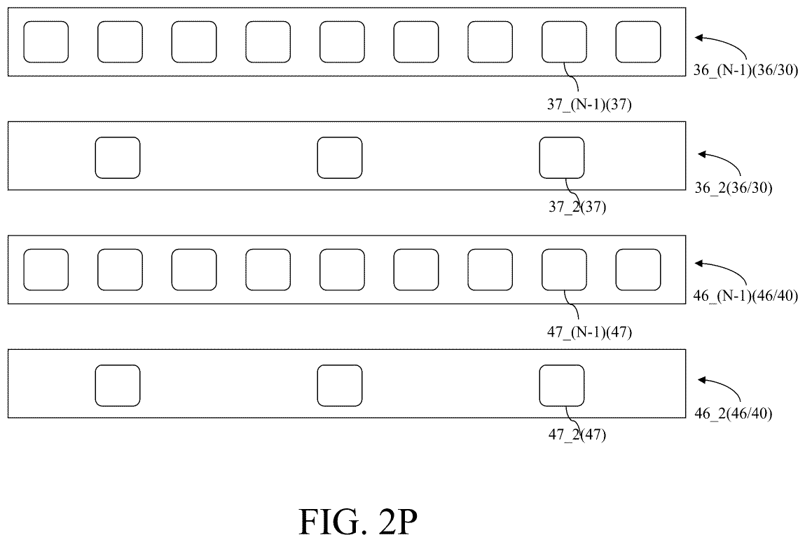

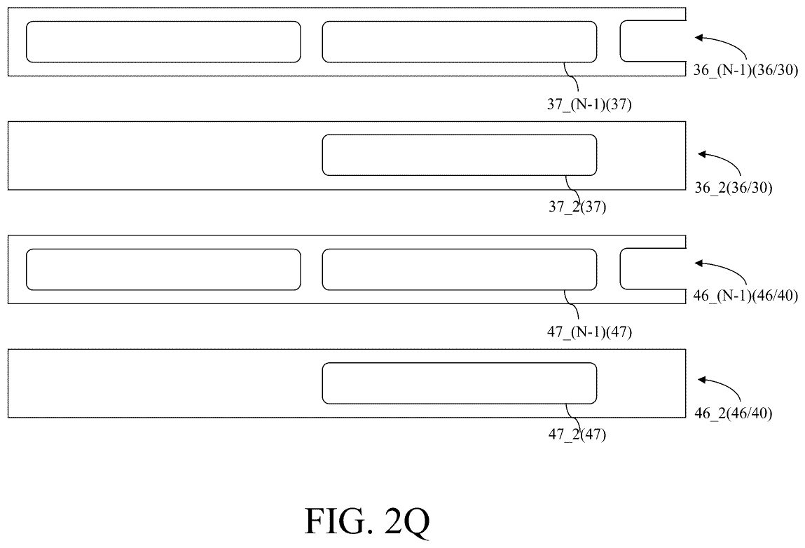

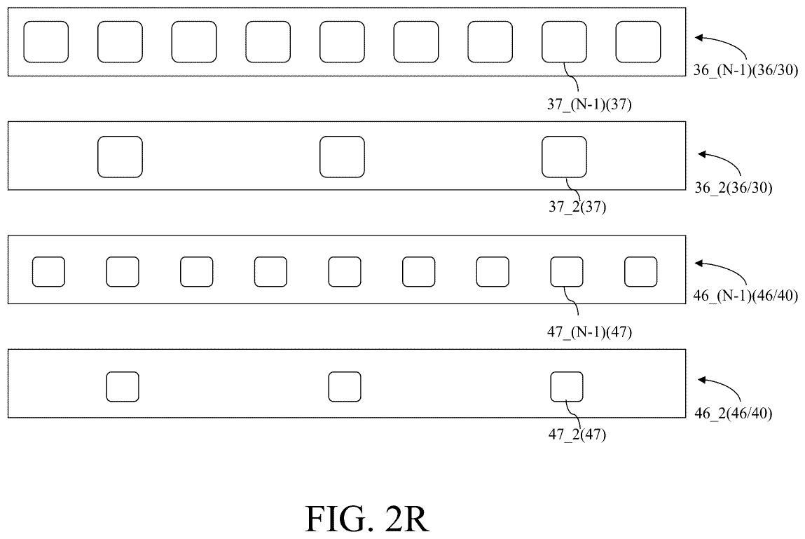

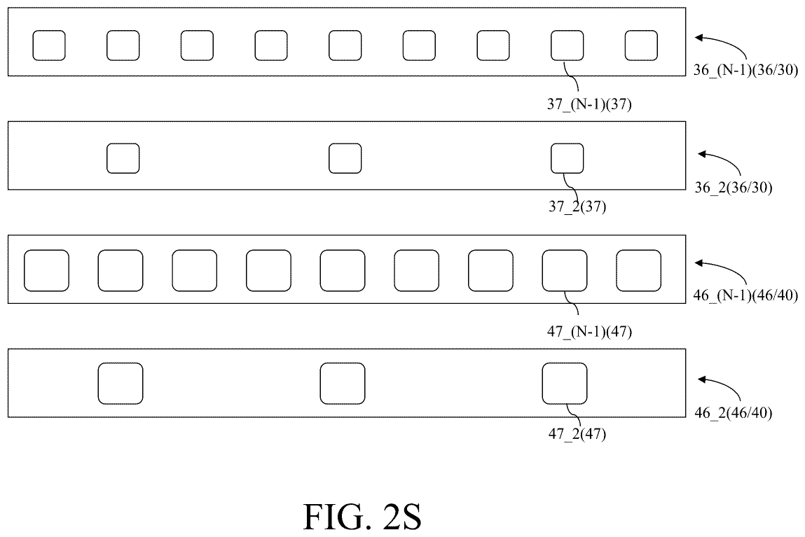

FIGS. 2A-2S are side views of portions of a gas distribution manifold 30 and a gas exhaust manifold 40 of various configurations of the frame cassette 100 of the present disclosure. Each of FIGS. 2A-2S includes, from top to bottom, a side view of a portion of a most distal perforated distribution manifold branch 36 of the gas distribution manifold 30 located between neighboring pairs of substrates 10 (i.e., the (N−1)-th perforated distribution manifold branch 36_(N−1)), a side view of a portion of a most proximal perforated distribution manifold branch 36 of the gas distribution manifold 30 located between neighboring pairs of substrates 10 (i.e., the second perforated distribution manifold branch 36_2), a side view of a portion of a most distal branch of the gas exhaust manifold 40 located between neighboring pairs of substrates 10 (i.e., the (N−1)-th perforated exhaust manifold branch 46_(N−1)), and a side view of a portion of a most proximal branch of the gas exhaust manifold 40 located between neighboring pairs of substrates 10 (i.e., the second perforated exhaust manifold branch 46_2).

As discussed above, for any set of at least two rows of distribution orifices 37 within the set of perforated distribution manifold branches 36 that excludes the bottommost perforated distribution manifold branch 36 (i.e., the first perforated distribution manifold branch 36_1) and the topmost perforated distribution manifold branch 36 (i.e., the N-th perforated distribution manifold branch 36_N), the values of the pneumatic conductance for the rows of distribution orifices 37 increase with the length of the gas flow path within the gas distribution manifold 30 from the inlet port 34 to a respective row of distribution orifices 37. The modulation of the pneumatic conductance across the rows of distribution orifices 37 may be effected by changes in the shapes and/or sizes of the distribution orifices 37, changes in the total number of distribution orifices 37 per each row of distribution orifices 37, changes in the vertical dimension of distribution orifices 37 within a respective row of distribution orifices 37, changes in the lateral dimension of each distribution orifice 37 within a respective row of distribution orifices 37, or any combination thereof.

Likewise, for any set of at least two rows of exhaust orifices 47 within the set of perforated exhaust manifold branches 46 that excludes the bottommost perforated exhaust manifold branch 46 (i.e., the first perforated exhaust manifold branch 46_1) and the topmost perforated exhaust manifold branch 46 (i.e., the N-th perforated exhaust manifold branch 46_N), the values of the pneumatic conductance for the rows of exhaust orifices 47 increase with the length of the gas flow path within the gas exhaust manifold 40 from a respective row of exhaust orifices 47 to the outlet port 44. The modulation of the pneumatic conductance across the rows of exhaust orifices 47 may be effected by changes in the shapes and/or sizes of the exhaust orifices 47, changes in the total number of exhaust orifices 47 per each row of exhaust orifices 47, changes in the vertical dimension of exhaust orifices 47 within a respective row of exhaust orifices 47, changes in the lateral dimension of each exhaust orifice 47 within a respective row of exhaust orifices 47, or any combination thereof.

The various embodiments of the perforated distribution manifold branches 36 and the perforated exhaust manifold branches 46 illustrated in FIGS. 2A-2S are nonlimiting examples that illustrate how the values of the pneumatic conductance may be modulated across the rows of distribution orifices 37, and across the rows of exhaust orifices 47. The height of each of the distribution orifices 37 may be generally in a range from 50 microns to 3 mm, although lesser and greater heights may also be used. The height of each of the exhaust orifices 47 may be generally in a range from 50 microns to 3 mm, although lesser and greater heights may also be used. The width of each of the distribution orifices 37 may be generally in a range from 50 microns to 50 mm, although lesser and greater widths may also be used. The width of each of the exhaust orifices 47 may be generally in a range from 50 microns to 50 mm, although lesser and greater widths may also be used. Alternative configurations for the distribution orifices 37 and/or the exhaust orifices 47 may be used provided that modulation in the values of the pneumatic conductance may be provided across the rows of distribution orifices 37, and/or across the rows of exhaust orifices 47.

Referring to FIG. 2A, a first embodiment configuration for the distribution orifices 37 and the exhaust orifices 47 is illustrated. The area of each distribution orifice 37 within the rows of distribution orifices 37 may increase with the length of the gas flow path within the gas distribution manifold 30 from the inlet port 34 to the respective row of distribution orifices 37. Thus, the area of each distribution orifice 37 within an overlying row of distribution orifices 37 may be greater than the area of each distribution orifice 37 within an underlying row of distribution orifices 37 within the set of all rows of distribution orifices 37 located between the topmost substrate 10 and the bottommost substrate 10. The area of each exhaust orifice 47 within the rows of exhaust orifices 47 may increase with the length of the gas flow path within the gas exhaust manifold 40 from the respective row of exhaust orifices 47 to the outlet port 44. Thus, the area of each exhaust orifice 47 within an overlying row of exhaust orifices 47 may be greater than the area of each exhaust orifice 47 within an underlying row of exhaust orifices 47 within the set of all rows of exhaust orifices 47 located between the topmost substrate 10 and the bottommost substrate 10. In one embodiment, the distribution orifices 37 and the exhaust orifices 47 may have circular shapes or oval shapes. The total number of distribution orifices 37 per each row of distribution orifices 37 may, or may not, be the same. The total number of exhaust orifices 47 per each row of exhaust orifices 47 may, or may not, be the same.

Referring to FIG. 2B, a second embodiment configuration for the distribution orifices 37 and the exhaust orifices 47 is illustrated. The second embodiment configuration for the distribution orifices 37 and the exhaust orifices 47 may be derived from the first embodiment configuration for the distribution orifices 37 and the exhaust orifices 47 by using the shapes of rounded rectangles for the distribution orifices 37 and the exhaust orifices 47. The total number of distribution orifices 37 per each row of distribution orifices 37 may, or may not, be the same. The total number of exhaust orifices 47 per each row of exhaust orifices 47 may, or may not, be the same.

Referring to FIG. 2C, a third embodiment configuration for the distribution orifices 37 and the exhaust orifices 47 is illustrated. The third embodiment configuration for the distribution orifices 37 and the exhaust orifices 47 may be derived from the second embodiment configuration for the distribution orifices 37 and the exhaust orifices 47 by laterally elongating the distribution orifices 37 and the exhaust orifices 47. The total number of distribution orifices 37 per each row of distribution orifices 37 may, or may not, be the same. The total number of exhaust orifices 47 per each row of exhaust orifices 47 may, or may not, be the same.

Referring to FIG. 2D, a fourth embodiment configuration for the distribution orifices 37 and the exhaust orifices 47 is illustrated. The fourth embodiment configuration for the distribution orifices 37 and the exhaust orifices 47 may be derived from the second embodiment configuration for the distribution orifices 37 and the exhaust orifices 47 by using a same first vertical dimension for each of the distribution orifices 37 and by modulating the lateral dimensions of the distribution orifices 37 from row to row, and by using a same second vertical dimension for each of the exhaust orifices 47 and by modulating the lateral dimensions of the exhaust orifices 47 from row to row. The total number of distribution orifices 37 per each row of distribution orifices 37 may, or may not, be the same. The total number of exhaust orifices 47 per each row of exhaust orifices 47 may, or may not, be the same.

Referring to FIG. 2E, a fifth embodiment configuration for the distribution orifices 37 and the exhaust orifices 47 is illustrated. The fifth embodiment configuration for the distribution orifices 37 and the exhaust orifices 47 may be derived from the fourth configuration for the distribution orifices 37 and the exhaust orifices 47 by laterally elongating the distribution orifices 37 and the exhaust orifices 47. The total number of distribution orifices 37 per each row of distribution orifices 37 may, or may not, be the same. The total number of exhaust orifices 47 per each row of exhaust orifices 47 may, or may not, be the same.

Referring to FIG. 2F, a sixth embodiment configuration for the distribution orifices 37 and the exhaust orifices 47 is illustrated. The sixth embodiment configuration for the distribution orifices 37 and the exhaust orifices 47 may be derived from the second configuration for the distribution orifices 37 and the exhaust orifices 47 by providing a general size offset between the average size of the distribution orifices 37 and the average size of the exhaust orifices 47. In the illustrated example, the average size of the distribution orifices 37 may be greater than the average size of the exhaust orifices 47 by a factor in a range from 1.1 to 10. The total number of distribution orifices 37 per each row of distribution orifices 37 may, or may not, be the same. The total number of exhaust orifices 47 per each row of exhaust orifices 47 may, or may not, be the same.

Referring to FIG. 2G, a seventh embodiment configuration for the distribution orifices 37 and the exhaust orifices 47 is illustrated. The seventh embodiment configuration for the distribution orifices 37 and the exhaust orifices 47 may be derived from the second embodiment configuration for the distribution orifices 37 and the exhaust orifices 47 by providing a general size offset between the average size of the distribution orifices 37 and the average size of the exhaust orifices 47. In the illustrated example, the average size of the exhaust orifices 47 may be greater than the average size of the distribution orifices 37 by a factor in a range from 1.1 to 10. The total number of distribution orifices 37 per each row of distribution orifices 37 may, or may not, be the same. The total number of exhaust orifices 47 per each row of exhaust orifices 47 may, or may not, be the same.

Referring to FIG. 2H, an eighth embodiment configuration for the distribution orifices 37 and the exhaust orifices 47 is illustrated. The total number of distribution orifices 37 per each row of distribution orifices 37 may increase with the length of the gas flow path within the gas distribution manifold 30 from the inlet port 34 to the respective row of distribution orifices 37. Thus, the total number of distribution orifices 37 within an overlying row of distribution orifices 37 may be greater than the total number of distribution orifices 37 within an underlying row of distribution orifices 37 within the set of all rows of distribution orifices 37 located between the topmost substrate 10 and the bottommost substrate 10. The total number of exhaust orifices 47 per each row of exhaust orifices 47 may increase with the length of the gas flow path within the gas exhaust manifold 40 from the respective row of exhaust orifices 47 to the outlet port 44. Thus, the total number of exhaust orifices 47 within an overlying row of exhaust orifices 47 may be greater than the total number of exhaust orifices 47 within an underlying row of exhaust orifices 47 within the set of all rows of exhaust orifices 47 located between the topmost substrate 10 and the bottommost substrate 10. The area of each distribution orifice 37 may, or may not, increase with the length of the gas flow path within the gas distribution manifold 30 from the inlet port 34 to the respective row of distribution orifices 37. The area of each exhaust orifice 47 may, or may not, increase with the length of the gas flow path within the gas exhaust manifold 40 from the respective row of exhaust orifices 47 to the outlet port 44. In one embodiment, the distribution orifices 37 and the exhaust orifices 47 may have circular shapes or oval shapes.

Referring to FIG. 2I, a ninth embodiment configuration for the distribution orifices 37 and the exhaust orifices 47 is illustrated. The ninth embodiment configuration for the distribution orifices 37 and the exhaust orifices 47 may be derived from the eighth embodiment configuration for the distribution orifices 37 and the exhaust orifices 47 by using the shapes of rounded rectangles for the distribution orifices 37 and the exhaust orifices 47. The area of each distribution orifice 37 may, or may not, increase with the length of the gas flow path within the gas distribution manifold 30 from the inlet port 34 to the respective row of distribution orifices 37. The area of each exhaust orifice 47 may, or may not, increase with the length of the gas flow path within the gas exhaust manifold 40 from the respective row of exhaust orifices 47 to the outlet port 44.

Referring to FIG. 2J, a tenth embodiment configuration for the distribution orifices 37 and the exhaust orifices 47 is illustrated. The tenth embodiment configuration for the distribution orifices 37 and the exhaust orifices 47 may be derived from the ninth embodiment configuration for the distribution orifices 37 and the exhaust orifices 47 by laterally elongating the distribution orifices 37 and the exhaust orifices 47. The area of each distribution orifice 37 may, or may not, increase with the length of the gas flow path within the gas distribution manifold 30 from the inlet port 34 to the respective row of distribution orifices 37. The area of each exhaust orifice 47 may, or may not, increase with the length of the gas flow path within the gas exhaust manifold 40 from the respective row of exhaust orifices 47 to the outlet port 44. In the illustrative example, the vertical dimension of the distribution orifices 37 increases with the length of the gas flow path within the gas distribution manifold 30 from the inlet port 34 to the respective row of distribution orifices 37, and the vertical dimension of the exhaust orifices 47 increases with the length of the gas flow path within the gas exhaust manifold 40 from the respective row of exhaust orifices 47 to the outlet port 44.

Referring to FIG. 2K, an eleventh embodiment configuration for the distribution orifices 37 and the exhaust orifices 47 is illustrated. The eleventh embodiment configuration for the distribution orifices 37 and the exhaust orifices 47 may be derived from the ninth embodiment configuration for the distribution orifices 37 and the exhaust orifices 47 by using a same first vertical dimension for each of the distribution orifices 37 and by modulating the lateral dimensions of the distribution orifices 37 from row to row, and by using a same second vertical dimension for each of the exhaust orifices 47 and by modulating the lateral dimensions of the exhaust orifices 47 from row to row.

Referring to FIG. 2L, a twelfth embodiment configuration for the distribution orifices 37 and the exhaust orifices 47 is illustrated. The twelfth configuration for the distribution orifices 37 and the exhaust orifices 47 may be derived from the eleventh embodiment configuration for the distribution orifices 37 and the exhaust orifices 47 by laterally elongating the distribution orifices 37 and the exhaust orifices 47. The area of each distribution orifice 37 increases with the length of the gas flow path within the gas distribution manifold 30 from the inlet port 34 to the respective row of distribution orifices 37. The area of each exhaust orifice 47 increases with the length of the gas flow path within the gas exhaust manifold 40 from the respective row of exhaust orifices 47 to the outlet port 44. In the illustrative example, the lateral dimension of the distribution orifices 37 increases with the length of the gas flow path within the gas distribution manifold 30 from the inlet port 34 to the respective row of distribution orifices 37, and the lateral dimension of the exhaust orifices 47 increases with the length of the gas flow path within the gas exhaust manifold 40 from the respective row of exhaust orifices 47 to the outlet port 44.

Referring to FIG. 2M, a thirteenth embodiment configuration for the distribution orifices 37 and the exhaust orifices 47 is illustrated. The thirteenth embodiment configuration for the distribution orifices 37 and the exhaust orifices 47 may be derived from the ninth embodiment configuration for the distribution orifices 37 and the exhaust orifices 47 illustrated in FIG. 2I by providing a general size offset between the average size of the distribution orifices 37 and the average size of the exhaust orifices 47. In the illustrated example, the average size of the distribution orifices 37 may be greater than the average size of the exhaust orifices 47 by a factor in a range from 1.1 to 10. The total number of distribution orifices 37 per each row of distribution orifices 37 may, or may not, be the same. The total number of exhaust orifices 47 per each row of exhaust orifices 47 may, or may not, be the same.

Referring to FIG. 2N, a fourteenth embodiment configuration for the distribution orifices 37 and the exhaust orifices 47 is illustrated. The fourteenth embodiment configuration for the distribution orifices 37 and the exhaust orifices 47 may be derived from the ninth embodiment configuration for the distribution orifices 37 and the exhaust orifices 47 illustrated in FIG. 2I by providing a general size offset between the average size of the distribution orifices 37 and the average size of the exhaust orifices 47. In the illustrated example, the average size of the exhaust orifices 47 may be greater than the average size of the distribution orifices 37 by a factor in a range from 1.1 to 10. The total number of distribution orifices 37 per each row of distribution orifices 37 may, or may not, be the same. The total number of exhaust orifices 47 per each row of exhaust orifices 47 may, or may not, be the same.

Referring to FIG. 2O, a fifteenth embodiment configuration for the distribution orifices 37 and the exhaust orifices 47 is illustrated. The total number of distribution orifices 37 per each row of distribution orifices 37 may increase with the length of the gas flow path within the gas distribution manifold 30 from the inlet port 34 to the respective row of distribution orifices 37. Thus, the total number of distribution orifices 37 within an overlying row of distribution orifices 37 may be greater than the total number of distribution orifices 37 within an underlying row of distribution orifices 37 within the set of all rows of distribution orifices 37 located between the topmost substrate 10 and the bottommost substrate 10. The total number of exhaust orifices 47 per each row of exhaust orifices 47 may increase with the length of the gas flow path within the gas exhaust manifold 40 from the respective row of exhaust orifices 47 to the outlet port 44. Thus, the total number of exhaust orifices 47 within an overlying row of exhaust orifices 47 may be greater than the total number of exhaust orifices 47 within an underlying row of exhaust orifices 47 within the set of all rows of exhaust orifices 47 located between the topmost substrate 10 and the bottommost substrate 10. The area of each distribution orifice 37 may be the same across the rows of distribution orifices 37. The area of each exhaust orifice 47 may be the same across the rows of exhaust orifices 47. In one embodiment, the distribution orifices 37 and the exhaust orifices 47 may have circular shapes or oval shapes.

Referring to FIG. 2P, a sixteenth embodiment configuration for the distribution orifices 37 and the exhaust orifices 47 is illustrated. The sixteenth embodiment configuration for the distribution orifices 37 and the exhaust orifices 47 may be derived from the fifteenth embodiment configuration for the distribution orifices 37 and the exhaust orifices 47 by using the shapes of rounded rectangles for the distribution orifices 37 and the exhaust orifices 47. The area of each exhaust orifice 47 may be the same across the rows of exhaust orifices 47. In one embodiment, the distribution orifices 37 and the exhaust orifices 47 may have circular shapes or oval shapes.

Referring to FIG. 2Q, a seventeenth embodiment configuration for the distribution orifices 37 and the exhaust orifices 47 is illustrated. The seventeenth embodiment configuration for the distribution orifices 37 and the exhaust orifices 47 may be derived from the sixteenth embodiment configuration for the distribution orifices 37 and the exhaust orifices 47 by laterally elongating the distribution orifices 37 and the exhaust orifices 47. The area of each exhaust orifice 47 may be the same across the rows of exhaust orifices 47. In one embodiment, the distribution orifices 37 and the exhaust orifices 47 may have circular shapes or oval shapes.

Referring to FIG. 2R, an eighteenth embodiment configuration for the distribution orifices 37 and the exhaust orifices 47 is illustrated. The eighteenth embodiment configuration for the distribution orifices 37 and the exhaust orifices 47 may be derived from the sixteenth embodiment configuration for the distribution orifices 37 and the exhaust orifices 47 illustrated in FIG. 2I by providing a general size offset between the average size of the distribution orifices 37 and the average size of the exhaust orifices 47. In the illustrated example, the average size of the distribution orifices 37 may be greater than the average size of the exhaust orifices 47 by a factor in a range from 1.1 to 10. The total number of distribution orifices 37 per each row of distribution orifices 37 may, or may not, be the same. The total number of exhaust orifices 47 per each row of exhaust orifices 47 may, or may not, be the same.

Referring to FIG. 2S, a nineteenth embodiment configuration for the distribution orifices 37 and the exhaust orifices 47 is illustrated. The nineteenth embodiment configuration for the distribution orifices 37 and the exhaust orifices 47 may be derived from the sixteenth embodiment configuration for the distribution orifices 37 and the exhaust orifices 47 illustrated in FIG. 2I by providing a general size offset between the average size of the distribution orifices 37 and the average size of the exhaust orifices 47. In the illustrated example, the average size of the exhaust orifices 47 may be greater than the average size of the distribution orifices 37 by a factor in a range from 1.1 to 10. The total number of distribution orifices 37 per each row of distribution orifices 37 may, or may not, be the same. The total number of exhaust orifices 47 per each row of exhaust orifices 47 may, or may not, be the same.

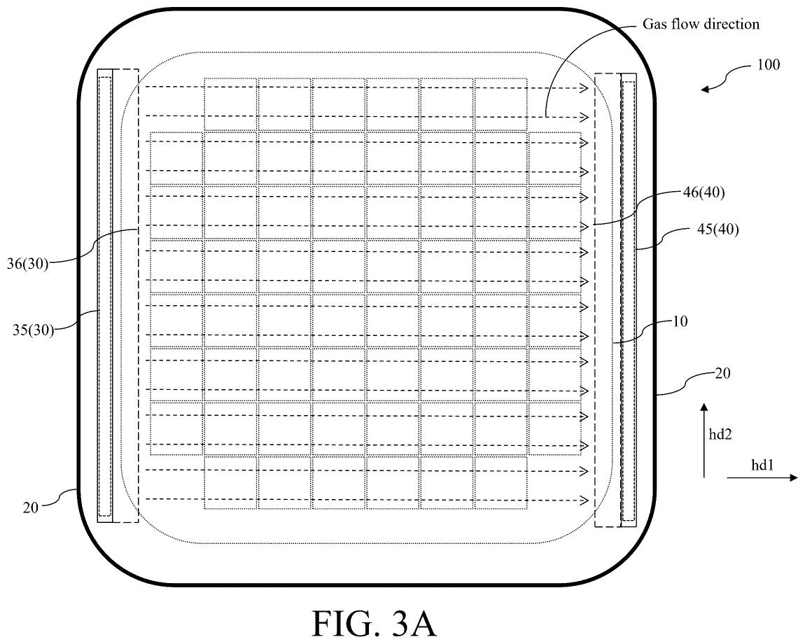

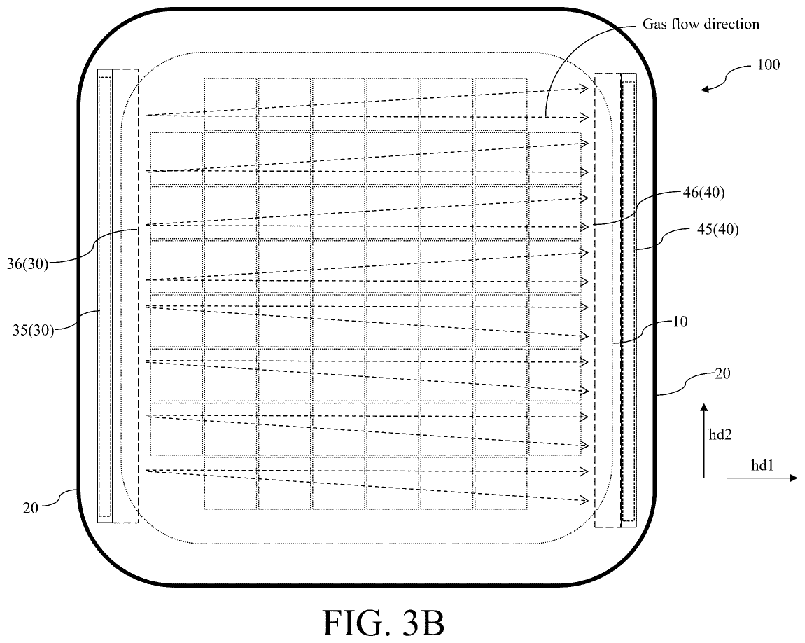

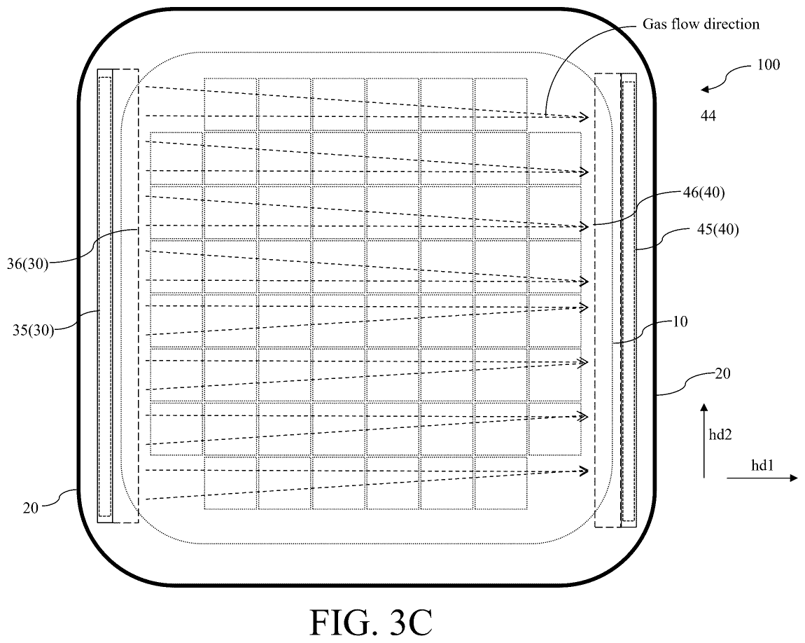

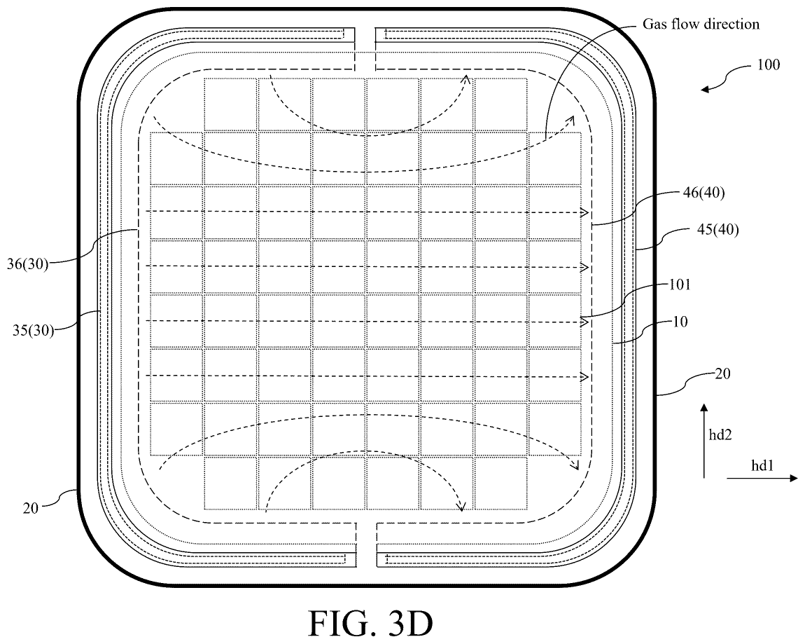

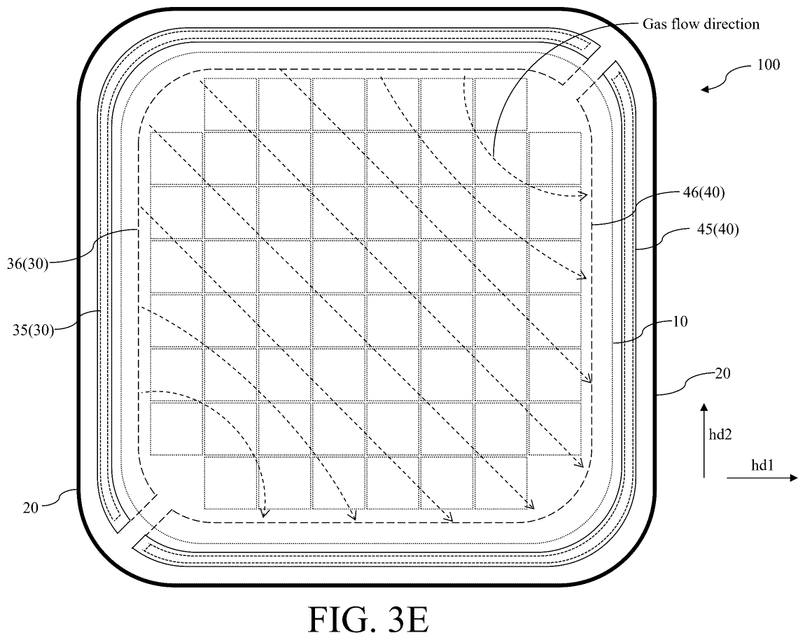

According to an aspect of the present disclosure, various horizontal flow directions for the purge gas may be provided by using various configurations for the gas distribution manifold 30 and the gas exhaust manifold 40. FIGS. 3A-3E are top-down views of various configurations of the frame cassette 100 according to an embodiment of the present disclosure.

Referring to FIG. 3A, a first embodiment configuration for the combination of the gas distribution manifold 30 and the gas exhaust manifold 40 is illustrated. In this configuration, the frame cassette 100 comprises a pair of first sidewalls that are parallel to a first horizontal direction hd1 and a pair of second sidewalls that are parallel to a second horizontal direction hd2. The distribution manifold main 35 may be located on a sidewall of the frame cassette 100 (such as a sidewall of an enclosure wall 20 that is parallel to the second horizontal direction hd2), and the exhaust manifold main 45 may be located on another sidewall of the frame cassette 100 (such as another sidewall of the enclosure wall 20 that is parallel to the second horizontal direction hd2). The rows of distribution orifices 37 and the rows of exhaust orifices 47 are laterally spaced apart along the first horizontal direction hd1. Distribution orifices 37 within each row of distribution orifices 37 are laterally spaced from one another along the second horizontal direction hd2. Exhaust orifices 47 within each row of exhaust orifices 47 are laterally spaced from one another along the first horizontal direction hd2. The flow direction of the purge gas may be parallel to the first horizontal direction hd1 within a predominant fraction of the volumes within the enclosure wall 20 that are not occupied by a solid phase material portion. As used herein, predominant fraction refers to a fraction that is at least 50% of the entirety.

Referring to FIG. 3B, a second embodiment configuration for the combination of the gas distribution manifold 30 and the gas exhaust manifold 40 is illustrated. The second embodiment configuration for the combination of the gas distribution manifold 30 and the gas exhaust manifold 40 may be derived from the first combination of the gas distribution manifold 30 and the gas exhaust manifold 40 by modifying the pattern of the distribution orifices 37 and/or the pattern of the exhaust orifices 47 such that the total number of distribution orifices 37 does not match that total number of exhaust orifices 47 between at least one vertically neighboring pair of substrates 10, and/or between each vertically neighboring pair of substrates 10. In the illustrated example shown in FIG. 3B, the total number of distribution orifices 37 is one half of the total number of exhaust orifices between a vertically neighboring pair of substrates 10. The flow direction of the purge gas is primarily along the first horizontal direction hd1, but has a horizontal divergence component along the second horizontal direction hd2.

Referring to FIG. 3C, a third embodiment configuration for the combination of the gas distribution manifold 30 and the gas exhaust manifold 40 is illustrated. The third embodiment configuration for the combination of the gas distribution manifold 30 and the gas exhaust manifold 40 may be derived from the first combination of the gas distribution manifold 30 and the gas exhaust manifold 40 by modifying the pattern of the distribution orifices 37 and/or the pattern of the exhaust orifices 47 such that the total number of distribution orifices 37 does not match that total number of exhaust orifices 47 between at least one vertically neighboring pair of substrates 10, and/or between each vertically neighboring pair of substrates 10. In the illustrated example shown in FIG. 3C, the total number of distribution orifices 37 is twice the total number of exhaust orifices between a vertically neighboring pair of substrates 10. The flow direction of the purge gas is primarily along the first horizontal direction hd1, but has a horizontal convergence component along the second horizontal direction hd2.

Referring to FIG. 3D, a fourth embodiment configuration for the combination of the gas distribution manifold 30 and the gas exhaust manifold 40 is illustrated. In this configuration, the frame cassette 100 comprises a pair of first sidewalls that are parallel to a first horizontal direction hd1 and a pair of second sidewalls that are parallel to a second horizontal direction hd2. The distribution manifold main 35 may be located on a first plurality of sidewalls of the frame cassette 100 (such as a sidewall of an enclosure wall 20 that is parallel to the second horizontal direction hd2 and about one half of two sidewalls of the enclosure wall 20 that are parallel to the first horizontal direction hd1), and the exhaust manifold main 45 may be located on a second plurality of sidewalls of the frame cassette 100 (such as another sidewall of the enclosure wall 20 that is parallel to the second horizontal direction hd2 and about one half of two sidewalls of the enclosure wall 20 that are parallel to the first horizontal direction hd1). In this embodiment, each of the perforated distribution manifold branches 36 and the perforated exhaust manifold branches 46 may have a respective U-shaped profile in a top-down view.

In one embodiment, a first subset of distribution orifices 37 within each row of distribution orifices 37 are laterally spaced from one another along the second horizontal direction hd2; and a second subset of the distribution orifices 37 within said each row of distribution orifices 37 are laterally spaced from one another along the first horizontal direction hd1. In one embodiment, a first subset of exhaust orifices 47 within each row of exhaust orifices 47 are laterally spaced from one another along the second horizontal direction hd2; and a second subset of the exhaust orifices 47 within said each row of exhaust orifices 47 are laterally spaced from one another along the first horizontal direction hd1. The flow direction of the purge gas may be parallel to the first horizontal direction hd1 along a strip region located around the geometrical center of the frame cassette 100 in a plan view. The flow direction of the purge gas may be curved in volumes that are proximal to lateral gaps between the gas distribution manifold 30 and the gas exhaust manifold 40.

Referring to FIG. 3E, a fifth embodiment configuration for the combination of the gas distribution manifold 30 and the gas exhaust manifold 40 is illustrated. In this configuration, the frame cassette 100 comprises a pair of first sidewalls that are parallel to a first horizontal direction hd1 and a pair of second sidewalls that are parallel to a second horizontal direction hd2. The distribution manifold main 35 may be located on a first plurality of sidewalls of the frame cassette 100 (such as a sidewall of an enclosure wall 20 that is parallel to the second horizontal direction hd2 and a sidewall of the enclosure wall 20 that is parallel to the first horizontal direction hd1), and the exhaust manifold main 45 may be located on a second plurality of sidewalls of the frame cassette 100 (such as another sidewall of the enclosure wall 20 that is parallel to the second horizontal direction hd2 and another sidewall of the enclosure wall 20 that is parallel to the first horizontal direction hd1). In this embodiment, each of the perforated distribution manifold branches 36 and the perforated exhaust manifold branches 46 may have a respective L-shaped profile in a top-down view.

In one embodiment, a first subset of distribution orifices 37 within each row of distribution orifices 37 are laterally spaced from one another along the second horizontal direction hd2; and a second subset of the distribution orifices 37 within said each row of distribution orifices 37 are laterally spaced from one another along the first horizontal direction hd1. In one embodiment, a first subset of exhaust orifices 47 within each row of exhaust orifices 47 are laterally spaced from one another along the second horizontal direction hd2; and a second subset of the exhaust orifices 47 within said each row of exhaust orifices 47 are laterally spaced from one another along the first horizontal direction hd1. The flow direction of the purge gas may be angled relative to the first horizontal direction hd1 and relative to the second horizontal direction hd2 in a plan view. The flow direction of the purge gas may be curved in volumes that are proximal to lateral gaps between the gas distribution manifold 30 and the gas exhaust manifold 40.

Referring collectively to FIGS. 1A-1D, 2A-2S, and 3A-3E and according to various embodiments of the present disclosure, a frame cassette 100 is provided, which comprises: a frame holder {30, 40, (38/48)} configured to hold a vertical stack of substrates 10; a gas distribution manifold 30 comprising an inlet port 34 and rows of distribution orifices 37 arranged along a vertical direction configured to inject a purge gas between vertically neighboring pairs of the substrates 10, wherein each row of distribution orifices 37 has a respective value for pneumatic conductance, and the values of the pneumatic conductance for the rows of distribution orifices 37 increase with the length of the gas flow path within the gas distribution manifold 30 from the inlet port 34 to a respective row of distribution orifices 37; and a gas exhaust manifold 40 comprising an outlet port 44 and rows of exhaust orifices 47 arranged along the vertical direction and configured to collect the purge gas.

In one embodiment, each row of exhaust orifices 47 has a respective value for pneumatic conductance, and the values of the pneumatic conductance for the rows of exhaust orifices 47 increase with the length of the gas flow path within the gas exhaust manifold 40 from a respective row of exhaust orifices 47 to the outlet port 44.

In one embodiment, the gas distribution manifold 30 comprising a portion of the frame holder {30, 40, (38/48)} and comprises perforated distribution manifold branches 36; each of the perforated distribution manifold branches 36 comprises a respective sidewall containing a respective row of distribution orifices 37 selected from the rows of distribution orifices 37; and each of the perforated distribution manifold branches 36 is configured to support a peripheral portion of a respective one of the substrates 10.

In one embodiment, the frame holder {30, 40, (38/48)} comprises distribution-side spacers 38 configured to support a peripheral portion of a respective one of the substrates 10; the gas distribution manifold 30 comprises perforated distribution manifold branches 36 each comprising a respective sidewall containing a respective row of distribution orifices 37 selected from the rows of distribution orifices 37; and each of the distribution-side spacers 38 contacts a top surface of a respective one of the perforated distribution manifold branches 36.

In one embodiment, for each pair of a row of distribution orifices 37 and a row of exhaust orifices 47 located between a respective vertically neighboring positions of the substrates 10, a horizontal plane including geometrical centers of the row of distribution orifices 37 is vertically offset relative to a horizontal plane including geometrical centers of the row of exhaust orifices 47.

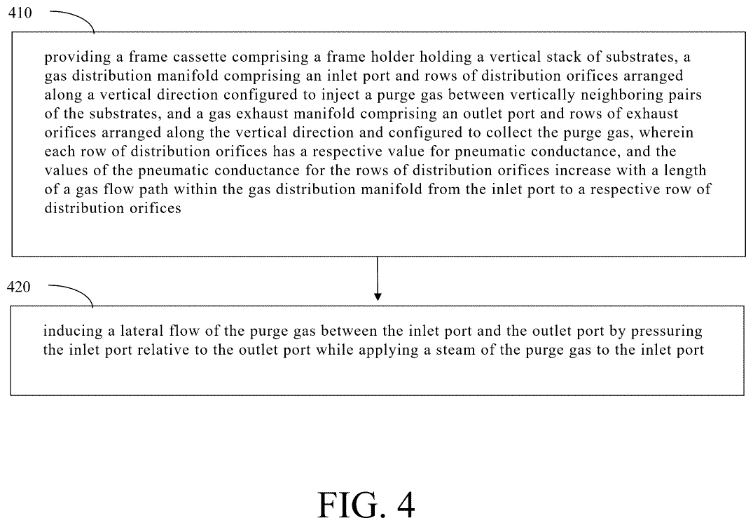

FIG. 4 is a first flowchart illustrating steps for flowing a purge gas in a frame cassette 100 according to an embodiment of the present disclosure.

Referring to step 410 and FIGS. 1A-1D, 2A-2S, and 3A-3E, a frame cassette 100 comprising a frame holder {30, 40, (38/48)} holding a vertical stack of substrates 10, a gas distribution manifold 30 comprising an inlet port 34 and rows of distribution orifices 37 arranged along a vertical direction configured to inject a purge gas between vertically neighboring pairs of the substrates 10, and a gas exhaust manifold 40 comprising an outlet port 44 and rows of exhaust orifices 47 arranged along the vertical direction and configured to collect the purge gas. Each row of distribution orifices 37 has a respective value for pneumatic conductance, and the values of the pneumatic conductance for the rows of distribution orifices 37 increase with the length of the gas flow path within the gas distribution manifold 30 from the inlet port 34 to a respective row of distribution orifices 37.

Referring to step 420 and FIGS. 1A-1D, 2A-2S, and 3A-3E, a lateral flow of the purge gas may be induced between the inlet port 34 and the outlet port 44 by pressuring the inlet port 34 relative to the outlet port 44 while applying a stream of the purge gas to the inlet port 34.

In one embodiment, each row of exhaust orifices 47 may have a respective value for pneumatic conductance, and the values of the pneumatic conductance for the rows of exhaust orifices 47 increase with a length of a gas flow path within the gas exhaust manifold 40 from a respective row of exhaust orifices 47 to the outlet port 44. In one embodiment, the gas distribution manifold 30 comprising a portion of the frame holder {30, 40, (38/48)} and comprises perforated distribution manifold branches 36; each of the perforated distribution manifold branches 36 comprises a respective sidewall containing a respective row of distribution orifices 37 selected from the rows of distribution orifices 37; and each of the perforated distribution manifold branches 36 is configured to support a peripheral portion of a respective one of the substrates 10. In one embodiment, the gas exhaust manifold 40 comprising a portion of the frame holder {30, 40, (38/48)} and comprises perforated exhaust manifold branches 36; each of the perforated exhaust manifold branches 36 comprises a respective sidewall containing a respective row of exhaust orifices 47 selected from the rows of exhaust orifices 47; and each of the perforated exhaust manifold branches 36 is configured to support a peripheral portion of a respective one of the substrates 10. In one embodiment, the frame holder {30, 40, (38/48)} comprises distribution-side spacers 38/48 configured to support a peripheral portion of a respective one of the substrates 10; the gas distribution manifold 30 comprises perforated distribution manifold branches 36 each comprising a respective sidewall containing a respective row of distribution orifices 37 selected from the rows of distribution orifices 37; and each of the distribution-side spacers 38 contacts a top surface of a respective one of the perforated distribution manifold branches 36. In one embodiment, the frame holder {30, 40, (38/48)} comprises exhaust-side spacers 48 configured to support a peripheral portion of a respective one of the substrates 10; the gas exhaust manifold 40 comprises perforated exhaust manifold branches 46 each comprising a respective sidewall containing a respective row of exhaust orifices 47 selected from the rows of exhaust orifices 47; and each of the exhaust-side spacers 48 contacts a top surface of a respective one of the perforated exhaust manifold branches 46. In one embodiment, for each pair of a row of distribution orifices 37 and a row of exhaust orifices 47 located between a respective vertically neighboring pair of substrates 10 selected from the vertical stack of substrates 10, an average of gas velocity vectors representing a gas flow velocity of the purge gas has a non-zero vertical component.

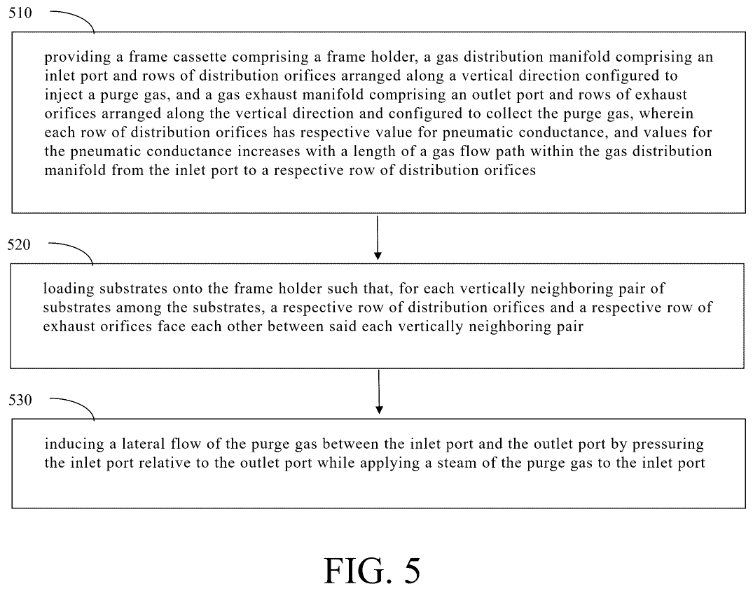

FIG. 5 is a second flowchart illustrating steps for storing substrates in a frame cassette according to an embodiment of the present disclosure.

Referring to step 510 and FIGS. 1A-1D, 2A-2S, and 3A-3E, a frame cassette 100 is provided, which comprises a frame holder {30, 40, (38/48)}, a gas distribution manifold 30 comprising an inlet port 34 and rows of distribution orifices 37 arranged along a vertical direction configured to inject a purge gas, and a gas exhaust manifold 40 comprising an outlet port 44 and rows of exhaust orifices 47 arranged along the vertical direction and configured to collect the purge gas. Each row of distribution orifices 37 has a respective value for pneumatic conductance, and values for the pneumatic conductance increase with the length of the gas flow path within the gas distribution manifold 30 from the inlet port 34 to a respective row of distribution orifices 37.

Referring to step 520 and FIGS. 1A-1D, 2A-2S, and 3A-3E, substrates 10 may be loaded onto the frame holder {30, 40, (38/48)} such that, for each vertically neighboring pair of substrates 10 selected from the substrates 10, a respective row of distribution orifices 37 and a respective row of exhaust orifices 47 face each other between said each vertically neighboring pair.

Referring to step 530 and FIGS. 1A-1D, 2A-2S, and 3A-3E, a lateral flow of the purge gas may be induced between the inlet port 34 and the outlet port 44 by pressuring the inlet port 34 relative to the outlet port 44 while applying a stream of the purge gas to the inlet port 34.

In one embodiment, the frame cassette 100 comprises a pair of first sidewalls that are parallel to a first horizontal direction and a pair of second sidewalls that are parallel to a second horizontal direction; the rows of distribution orifices 37 and the rows of exhaust orifices 47 are laterally spaced apart along the first horizontal direction; and distribution orifices 37 within each row of distribution orifices 37 are laterally spaced from one another along the second horizontal direction. In one embodiment, the frame cassette 100 comprises a pair of first sidewalls that are parallel to a first horizontal direction and a pair of second sidewalls that are parallel to a second horizontal direction; a first subset of the distribution orifices 37 within each row of the distribution orifices 37 are laterally spaced from one another along the second horizontal direction; and a second subset of the distribution orifices 37 within said each row of the distribution orifices 37 are laterally spaced from one another along the first horizontal direction. In one embodiment, an area of each distribution orifice within the rows of the distribution orifices increases with the length of the gas flow path within the gas distribution manifold from the inlet port to the respective row of the distribution orifices. In one embodiment, a total number of the distribution orifices 37 per each row of the distribution orifices 37 increases with the length of the gas flow path within the gas distribution manifold from the inlet port to the respective row of the distribution orifices. In one embodiment, a vertical dimension of distribution orifices 37 within a respective row of the distribution orifices 37 increases with the length of the gas flow path within the gas distribution manifold 30 from the inlet port to the respective row of the distribution orifices 37. In one embodiment, a lateral dimension of the distribution orifices 37 within a respective row of the distribution orifices 37 increases with the length of the gas flow path within the gas distribution manifold 30 from the inlet port 34 to the respective row of the distribution orifices 37.

Various embodiments disclosed herein provide a novel high-efficiency inner air purge design for frame cassettes 100 used in semiconductor manufacturing. Embodiments of the present disclosure use a gas distribution manifold 30 including a plurality of perforated distribution manifold branches 36 and a gas exhaust manifold 40 including a plurality of perforated exhaust manifold branches 46. Rows of distribution orifices 37 and rows of exhaust orifices 47 are configured to provide uniform distribution of the purge gas within the frame cassette 100, addressing the issue of non-uniform purge gas flow in traditional frame cassettes with single bottom vents. The retention of purge gas in localized volumes is prevented and contamination on substrate surfaces, which may result in non-bond defects and reduced manufacturing yields in bonding processes, may be avoided through use of the frame cassette 100 of the present disclosure.

The gas distribution manifold 30 comprises a plurality of perforated distribution manifold branches 36, each including a respective row of distribution orifices 37, and a plurality of perforated exhaust manifold branches 46, each including a respective row of exhaust orifices 47. Pneumatic conductance of the row of distribution orifices 37 and the row of exhaust orifices 47 are varied along the vertical direction so that increases in the gas travel distance are compensated by larger pneumatic conductance for each row. Thus, the greater the size and number of orifices (37, 47), the higher the pneumatic conductance, allowing for more efficient gas flow. A relatively uniform purge gas flow is provided within the entire volume of the frame cassette 100.

The purge gas flows from an external purge gas supply source, through the gas supply connector 52, through the inlet port 34 of the gas distribution manifold 30, through the distribution manifold main 35 of the gas distribution manifold 30, through the perforated distribution manifold branches 36, over or under horizontal surfaces of the substrates 10, through the perforated exhaust manifold branches 46, through the exhaust manifold main 45, through the outlet port 44 of the gas exhaust manifold 40, through the gas exhaust connector 58, and to an external purge gas drain. Filters (not shown) may be provided at the gas supply connector 52 and/or at the gas exhaust connector 58 as needed. The differential in the values of the pneumatic conductance across the perforated distribution manifold branches 36 as a function of a gas flow distance from inlet port 34 in combination with the differential in the values of the pneumatic conductance across the perforated exhaust manifold branches 46 as a function of a gas flow distance to the outlet port 44 provides uniform gas flow rate across the entire volume within the enclosure wall 20 of the frame cassette 100.

The frame cassette 100 of the various disclosed embodiments provides several advantages over traditional designs. The gas distribution manifold 30 and the gas exhaust manifold 40 of the present disclosure provide uniform distribution and effective purging of gases from the frame cassette 100, reducing the likelihood of contamination and non-bond defects. By preventing surface contamination and ensuring efficient gas removal, the various embodiments disclosed herein may improve manufacturing yields.

Embodiments of the present disclosure may provide higher manufacturing yields and more reliable semiconductor devices for various types of semiconductor devices. In an illustrative example, in the context of advanced packaging technologies such as system on integrated chips (SoIC), chip on wafer on substrate (CoWoS), three-dimensional integrated circuit technologies, and integrated fan-out (InFO), the design demonstrates high adaptability and efficiency. SoIC, which involves three-dimensional stacking of chips within a single package, benefits from the effective gas removal facilitated by this design, thereby preventing defects that could affect chip integration. In CoWoS technology, which integrates multiple chips on a single wafer mounted on a substrate, the uniform gas distribution ensures a clean assembly process, enhancing the overall integrity and performance of the assembled chips. Three-dimensional integrated circuit technologies, encompassing a family of three-dimensional silicon stacking and advanced packaging technologies, requires a clean environment for the high-density integration of components, which is maintained by the innovative ventilation system. Additionally, InFO technology, which involves high-density interconnects within a compact package for mobile and high-performance computing applications, benefits from the improved air purge system by eliminating internal gas residues that could impair electrical performance.

The foregoing outlines features of several embodiments so that those skilled in the art may better understand the aspects of the present disclosure. Each embodiment described using the term “comprises” also inherently discloses additional embodiments in which the term “comprises” is replaced with “consists essentially of” or with the term “consists of,” unless expressly disclosed otherwise herein. Whenever two or more elements are listed as alternatives in a same paragraph or in different paragraphs, a Markush group including a listing of the two or more elements is also impliedly disclosed. Whenever the auxiliary verb “may” is used in this disclosure to describe formation of an element or performance of a processing step, an embodiment in which such an element or such a processing step is not performed is also expressly contemplated, provided that the resulting apparatus or device may provide an equivalent result. As such, the auxiliary verb “may” as applied to formation of an element or performance of a processing step should also be interpreted as “may” or as “may, or may not” whenever omission of formation of such an element or such a processing step is capable of providing the same result or equivalent results, the equivalent results including somewhat superior results and somewhat inferior results. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of flowing a purge gas in a frame cassette, comprising:
providing the frame cassette comprising a frame holder holding a vertical stack of substrates, a gas distribution manifold comprising an inlet port and rows of distribution orifices arranged along a vertical direction configured to inject a purge gas between vertically neighboring pairs of the substrates, and a gas exhaust manifold comprising an outlet port and rows of exhaust orifices arranged along the vertical direction and configured to collect the purge gas, wherein each row of distribution orifices has a respective value for pneumatic conductance, and the values of the pneumatic conductance for the rows of distribution orifices increase with a length of a gas flow path within the gas distribution manifold from the inlet port to a respective row of distribution orifices; and
inducing a lateral flow of the purge gas between the inlet port and the outlet port by pressuring the inlet port relative to the outlet port while applying a stream of the purge gas to the inlet port.

2. The method of claim 1, wherein each row of exhaust orifices has a respective value for pneumatic conductance, and the values of the pneumatic conductance for the rows of exhaust orifices increase with a length of a gas flow path within the gas exhaust manifold from a respective row of exhaust orifices to the outlet port.

3. The method of claim 1, wherein:
the gas distribution manifold comprising a portion of the frame holder and comprises perforated distribution manifold branches;
each of the perforated distribution manifold branches comprises a respective sidewall containing a respective row of distribution orifices selected from the rows of distribution orifices; and
each of the perforated distribution manifold branches is configured to support a peripheral portion of a respective one of the substrates.

4. The method of claim 1, wherein:
the gas exhaust manifold comprising a portion of the frame holder and comprises perforated exhaust manifold branches;
each of the perforated exhaust manifold branches comprises a respective sidewall containing a respective row of exhaust orifices selected from the rows of exhaust orifices; and
each of the perforated exhaust manifold branches is configured to support a peripheral portion of a respective one of the substrates.

5. The method of claim 1, wherein:
the frame holder comprises distribution-side spacers configured to support a peripheral portion of a respective one of the substrates;
the gas distribution manifold comprises perforated distribution manifold branches each comprising a respective sidewall containing a respective row of distribution orifices selected from the rows of distribution orifices; and
each of the distribution-side spacers contacts a top surface of a respective one of the perforated distribution manifold branches.

6. The method of claim 1, wherein:
the frame holder comprises exhaust-side spacers configured to support a peripheral portion of a respective one of the substrates;
the gas exhaust manifold comprises perforated exhaust manifold branches each comprising a respective sidewall containing a respective row of exhaust orifices selected from the rows of exhaust orifices; and
each of the exhaust-side spacers contacts a top surface of a respective one of the perforated exhaust manifold branches.

7. The method of claim 1, wherein, for each pair of a row of distribution orifices and a row of exhaust orifices located between a respective vertically neighboring pair of substrates selected from the vertical stack of substrates, an average of gas velocity vectors representing a gas flow velocity of the purge gas has a non-zero vertical component.

8. A method of storing substrates in a frame cassette, comprising:
providing the frame cassette comprising a frame holder, a gas distribution manifold comprising an inlet port and rows of distribution orifices arranged along a vertical direction configured to inject a purge gas, and a gas exhaust manifold comprising an outlet port and rows of exhaust orifices arranged along the vertical direction and configured to collect the purge gas, wherein each row of distribution orifices has a respective value for pneumatic conductance, and values for the pneumatic conductance increase with a length of a gas flow path within the gas distribution manifold from the inlet port to a respective row of distribution orifices;
loading substrates onto the frame holder such that, for each vertically neighboring pair of substrates selected from the substrates, a respective row of distribution orifices and a respective row of exhaust orifices face each other between said each vertically neighboring pair; and
inducing a lateral flow of the purge gas between the inlet port and the outlet port by pressuring the inlet port relative to the outlet port while applying a stream of the purge gas to the inlet port.

9. The method of claim 8, wherein:
the frame cassette comprises a pair of first sidewalls that are parallel to a first horizontal direction and a pair of second sidewalls that are parallel to a second horizontal direction;
the rows of distribution orifices and the rows of exhaust orifices are laterally spaced apart along the first horizontal direction; and
distribution orifices within each row of distribution orifices are laterally spaced from one another along the second horizontal direction.

10. The method of claim 8, wherein:
the frame cassette comprises a pair of first sidewalls that are parallel to a first horizontal direction and a pair of second sidewalls that are parallel to a second horizontal direction;
a first subset of the distribution orifices within each row of the distribution orifices are laterally spaced from one another along the second horizontal direction; and
a second subset of the distribution orifices within said each row of the distribution orifices are laterally spaced from one another along the first horizontal direction.

11. The method of claim 8, wherein an area of each distribution orifice within the rows of the distribution orifices increases with the length of the gas flow path within the gas distribution manifold from the inlet port to the respective row of the distribution orifices.

12. The method of claim 8, wherein a total number of the distribution orifices per each row of the distribution orifices increases with the length of the gas flow path within the gas distribution manifold from the inlet port to the respective row of the distribution orifices.

13. The method of claim 8, wherein a vertical dimension of distribution orifices within a respective row of the distribution orifices increases with the length of the gas flow path within the gas distribution manifold from the inlet port to the respective row of the distribution orifices.

14. The method of claim 8, wherein a lateral dimension of the distribution orifices within a respective row of the distribution orifices increases with the length of the gas flow path within the gas distribution manifold from the inlet port to the respective row of the distribution orifices.

15. A frame cassette comprising:
a frame holder configured to hold a vertical stack of substrates;
a gas distribution manifold comprising an inlet port and rows of distribution orifices arranged along a vertical direction configured to inject a purge gas between vertically neighboring pairs of the substrates, wherein each row of distribution orifices has a respective value for pneumatic conductance, and the values of the pneumatic conductance for the rows of distribution orifices increase with a length of a gas flow path within the gas distribution manifold from the inlet port to a respective row of distribution orifices; and
a gas exhaust manifold comprising an outlet port and rows of exhaust orifices arranged along the vertical direction and configured to collect the purge gas.

16. The frame cassette of claim 15, further comprising:
a gas inlet seal configured to provide a gas inlet passage toward the inlet port upon docking with a mating gas supply connector; and
a gas outlet seal configured to provide a gas outlet passage from the outlet port upon docking with a mating gas exhaust connector.

17. The frame cassette of claim 15, wherein each row of exhaust orifices has a respective value for pneumatic conductance, and the values of the pneumatic conductance for the rows of exhaust orifices increase with a length of a gas flow path within the gas exhaust manifold from a respective row of exhaust orifices to the outlet port.

18. The frame cassette of claim 15, wherein:
the gas distribution manifold comprising a portion of the frame holder and comprises perforated distribution manifold branches;
each of the perforated distribution manifold branches comprises a respective sidewall containing a respective row of distribution orifices selected from the rows of distribution orifices; and
each of the perforated distribution manifold branches is configured to support a peripheral portion of a respective one of the substrates.

19. The frame cassette of claim 15, wherein:
the frame holder comprises distribution-side spacers configured to support a peripheral portion of a respective one of the substrates;
the gas distribution manifold comprises perforated distribution manifold branches each comprising a respective sidewall containing a respective row of distribution orifices selected from the rows of distribution orifices; and
each of the distribution-side spacers contacts a top surface of a respective one of the perforated distribution manifold branches.

20. The frame cassette of claim 15, wherein, for each pair of a row of distribution orifices and a row of exhaust orifices located between a respective vertically neighboring positions of the substrates, a horizontal plane including geometrical centers of the row of distribution orifices is vertically offset relative to a horizontal plane including geometrical centers of the row of exhaust orifices.
